(19) United States
(12) Patent Application Publication
(10) Pub. No.: US 2025/0081691 A1
(43) Pub. Date: Mar. 6, 2025

(54) Photonic Integrated Circuit Devices including Radiation Emitting Diodes Configured to Emit Radiation Through Semiconductor Waveguides

(71) Applicant: The Government of the United States of America, as represented by the Secretary of the Navy, Arlington, VA (US)

(72) Inventors: Marcel W. PRUESSNER, Chevy Chase, MD (US); Nathan F. TYNDALL, Alexandria, VA (US); Todd H. STIEVATER, Arlington, VA (US)

(73) Assignee: The Government of the United States of America, as represented by the Secretary of the Navy, Arlington, VA (US)

(21) Appl. No.: 18/648,584

(22) Filed: Apr. 29, 2024

Related U.S. Application Data
(60) Provisional application No. 63/500,359, filed on May 5, 2023.

(51) Int. Cl. H01L 33/58; G01J 3/02; G01J 3/51; H01L 33/00; H01L 33/62

(52) U.S. Cl. CPC H10H 20/855; G01J 3/0259; G01J 3/51; H10H 20/81; H10H 20/857

(57) ABSTRACT

Photonic integrated circuit (PIC) devices are disclosed. Such PIC devices include a substrate and a semiconductor waveguide on a surface of the substrate. A p-type semiconductor layer is on the surface of the substrate, with the p-type semiconductor layer being on a first side of the semiconductor waveguide. An n-type semiconductor layer is on the surface of the substrate, with the n-type semiconductor layer being on a second side of the semiconductor waveguide so that a region of the semiconductor waveguide is between the p-type and n-type semiconductor layers. Moreover, the p-type semiconductor layer, the n-type semiconductor layer, and the region of the semiconductor waveguide between the n-type and p-type semiconductor layers define a radiation emitting diode configured to emit radiation through the semiconductor waveguide.

### CROSS-REFERENCE TO RELATED APPLICATIONS

This Application is a Nonprovisional Utility Patent Application and claims the benefit of priority under 35 U.S.C. Sec. 119 based on U.S. Provisional Patent Application No. 63/500,359 filed on May 5, 2023. The disclosure of Provisional Application No. 63/500,359 and all references cited herein are hereby incorporated in their entirety by reference into the present disclosure.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case #211557-US2.

### TECHNICAL FIELD

The present disclosure relates to the field of photonics, and more particularly to photonic integrated circuit devices.

### BACKGROUND OF THE INVENTION

Silicon photonics combines the technological maturity of complementary metal-oxide semiconductor (CMOS) microelectronics fabrication with the ultra-high bandwidth of light traveling in nanophotonic waveguides. At present, CMOS foundries can provide many of the key components for optical processing: high-speed electro-optic modulators, photodetectors, and low-loss waveguides. However, the materials commonly-available in foundries (i.e., silicon, silicon dioxide, silicon nitride, etc.) may be unable to emit or amplify the optical radiation-a function that may be important/critical for fully-integrated optical systems (see, Reference [1]). Though significant progress in bringing light emission closer to the waveguides using techniques such as wafer-bonding (see Reference [2]), III-V semiconductor growth on silicon (see Reference [3]), or 2.5D packaging (see Reference [4]) has been made, the lack of a sufficiently efficient on-chip light source in silicon photonics continues to impede its maturation.

Despite silicon's indirect bandgap, optical emission from injected carriers has been observed previously in surface-normal geometries. Both electroluminescence from interband recombination in forward-biased diodes (see References [5], [6], [7], and [8]) and impact-ionization-based emission in reverse-biased P-(i)-N diodes (see, References [5], [9], [10], and [11]) have been reported. However, poor quantum efficiency of the electrical to optical conversion has limited the further development of integrated electrically-pumped emitters. CMOS-compatible silicon light-emitting diodes (LEDs) have been explored (see, Referenced [12], [13], and [14]).

More recently, the growth of silicon PICs has resulted in potential applications beyond data communications and telecommunications, including lidar, quantum computing, and chemical and biological sensing. Though some photonic sensing techniques, such as refractive-index sensing (see, References [15] and [16]) or waveguide-enhanced Raman spectroscopy (WERS) (see, References [17] and [18]) may only require a fixed laser source, infrared (IR) spectroscopy may require a source with a broad optical bandwidth-often hundreds of nanometers. IR spectroscopies adapted for PICs include Fourier transform infrared spectroscopy (FTIR) (see, Reference [19]), waveguide infrared absorption spectroscopy (WIRAS) (see, References [20] and [21]), microring absorption spectroscopy (see, References [22] and [23]) and tunable laser spectroscopy (see, Reference [24]). All of these demonstrations used an off-chip optical source, compromising the promise of integrated photonics.

### SUMMARY OF THE INVENTION

This summary is intended to introduce in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

According to some embodiments of inventive concepts, a photonic integrated circuit device includes a substrate and a semiconductor waveguide on a surface of the substrate. A p-type semiconductor layer is on the surface of the substrate, with the p-type semiconductor layer being on a first side of the semiconductor waveguide. An n-type semiconductor layer is on the surface of the substrate, with the n-type semiconductor layer being on a second side of the semiconductor waveguide. Accordingly, a region of the semiconductor waveguide is between the p-type and n-type semiconductor layers, and the p-type semiconductor layer, the n-type semiconductor layer, and the region of the semiconductor waveguide between the n-type and p-type semiconductor layers define a radiation emitting diode configured to emit radiation through the semiconductor waveguide.

### BRIEF DESCRIPTION OF DRAWINGS

Examples of embodiments of inventive concepts may be more clearly understood from the following detailed description taken in conjunction with the accompanying drawings in which:

FIG. 1A is a top view of a photonic integrated circuit (PIC) device including a radiation emitting P-i-N diode according to some embodiments of inventive concepts;

FIGS. 1B, 1C, and 1D are a cross sectional views of the PIC of FIG. 1A taken along section lines 1B-1B′, 1C-1C′, and 1D-1D′ respectively;

FIG. 2A is a top view of a photonic integrated circuit (PIC) device including a radiation emitting P-i-N diode according to some embodiments of inventive concepts;

FIGS. 2B, 2C, and 2D are a cross sectional views of the PIC of FIG. 2A taken along section lines 2B-2B′, 2C-2C′, and 2D-2D′, respectively;

FIG. 3A is a top view of a photonic integrated circuit (PIC) device including a radiation emitting P-i-N diode according to some embodiments of inventive concepts;

FIGS. 3B, 3C, and 3D are a cross sectional views of the PIC of FIG. 3A taken along section lines 3B-3B′, 3C-3C′, and 3D-3D′, respectively;

FIG. 4A is a top view of a photonic integrated circuit (PIC) device including a radiation emitting P-i-N diode according to some embodiments of inventive concepts;

FIGS. 4B, 4C, and 4D are a cross sectional views of the PIC of FIG. 4A taken along section lines 4B-4B′, 4C-4C′, and 4D-4D′, respectively;

FIG. 5A is schematic representation of a PIC device including a driving circuit, an optical device, and a radiation emitting P-i-N diode according to some embodiments of inventive concepts;

FIG. 5B is a graph illustrating operations of radiation emitting P-i-N diodes of FIGS. 2A-C and 4A-C according to some embodiments of inventive concepts;

FIG. 6A is a schematic representation of a measurement set up including a P-i-N waveguide emitter and spectrometer according to some embodiments of inventive concepts;

FIGS. 6B and 6C are graphs illustrating power spectral density measurements taken using the measurement set up of FIG. 6A according to some embodiments of inventive concepts;

FIG. 7A is a graph illustrating reverse-bias waveguide power spectral densities according to some embodiments of inventive concepts;

FIG. 7B is a graph illustrating power vs. reverse current for two wavelength ranges according to some embodiments of inventive concepts;

FIG. 8 is a measurement set up that may be used with waveguide emitters according to some embodiments of inventive concepts;

FIG. 9A illustrates a device chip including two Mach-Zehnder Interferometers (MZIs) that may be used as optical devices according to some embodiments of inventive concepts;

FIGS. 9B and 9C are graphs illustrating measured MZI spectra using a waveguide emitter with the device chip of FIG. 9A;

FIG. 10A illustrates a device chip including a 2×2 lattice filter having different delays DD and a broadband directional coupler DC that may be used as optical devices according to some embodiments of inventive concepts;

FIG. 10B is a graph illustrating a measured lattice filter response using a waveguide emitter with the device chip of FIG. 10A;

FIG. 11 illustrates a device chip including a spiral sensor that may be used as an optical device according to some embodiments of inventive concepts;

FIG. 12A is a graph illustrating H₂O reference absorptions, and FIG. 12B is a graph illustrating the WIRAS spectrum of water obtained using a waveguide emitter according to some embodiments of inventive concepts;

FIG. 13A is a graph illustrating isopropyl alcohol reference absorptions, and FIG. 13B is a graph illustrating the WIRAS spectrum of isopropyl alcohol obtained using a waveguide emitter according to some embodiments of inventive concepts; and

FIG. 14 illustrates reverse bias operation yielding a broadband output according to some embodiments of inventive concepts.

### DETAILED DESCRIPTION OF THE INVENTION

Aspects and features of the present disclosure will now be described more fully with reference to the accompanying drawings. The following description shows, by way of example, combinations and configurations in which aspects, features, and embodiments of inventive concepts can be put into practice. It will be understood that the disclosed aspects, features, and/or embodiments are merely examples, and that one skilled in the art may use other aspects, features, and/or embodiments or make functional and/or structural modifications without departing from the scope of the present disclosure. Moreover, like reference numerals refer to like elements throughout, and sizes of each of the elements may be exaggerated for clarity and/or convenience of explanation.

The emergence of optical foundries has enabled wafer-level fabrication of large-scale photonic integrated circuits (PICs) for applications ranging from data communication to chemical sensing. The development of an integrated light source in silicon for CMOS photonic integrated circuits has been a goal for decades, but silicon's indirect bandgap has been an obstacle to achieving practical sources on-chip. Monolithic and heterogeneous integration, as well as co-packaging optical sources, are under development, but these approaches increase system size, complexity, and cost. The present disclosure describes a broadband silicon light source fully integrated with single-mode waveguides fabricated in a 300-mm CMOS foundry.

According to some embodiments, a reverse-biased p-i-n diode in a subwavelength silicon waveguide emits broadband near-infrared optical radiation into the waveguide mode, resulting in nanowatts (nW) of guided optical power from less than 5 mA of electrical current. According to some embodiments, detected infrared emission may span from 900 nm to 1600 nm in wavelength, where detection may be limited by the measurement apparatus. Stated in other words, actual emission may span wavelengths below 900 nm and/or above 1600 nm. Physical mechanisms for this reverse-bias emission are disclosed, and the measured spectra is shown to have excellent agreement with theoretical predictions for thermal emission from hot carriers in a one-dimensional (waveguide) geometry. Utility of on-chip emitters of the present disclosure are demonstrated by using this broadband source to characterize photonic components over a wavelength range spanning more than 400 nm. Uses of this source for waveguide infrared absorption spectroscopy (WIRAS) using water and isopropyl alcohol as example analytes are also disclosed. Embodiments of this foundry-ready silicon optical source are expected to find immediate application in PICs for on-chip metrology, component characterization, and/or sensing.

Some embodiments of the present disclosure demonstrate broadband emission from current injection within single mode silicon waveguides fabricated in a standard optical foundry process. This infrared emission (which may span in wavelength from the silicon bandedge to beyond the upper detection range of the spectrometer that was used) is efficiently coupled into the propagating mode of the silicon waveguide. The present disclosure derives a new theoretical framework to understand this emission, which is based on Planck's radiation law modified for hot carriers in a one-dimensional photonic (i.e., waveguide) geometry. Usefulness of this source is established for characterization of broadband waveguide components such as couplers and filters, as well as absorption spectroscopy of liquid analytes in sensing trenches on photonic integrated circuits PICs. The silicon waveguide emitter of some embodiments may be fabricated using standard layers and/or components in a state-of-the-art CMOS photonics foundry (e.g., AIM Photonics). As such, it can be immediately integrated into more sophisticated on-chip sensor systems and/or component characterization PIC systems.

According to some embodiments of inventive concepts, a P-i-N waveguide radiation emitting diode may be provided as discussed below.

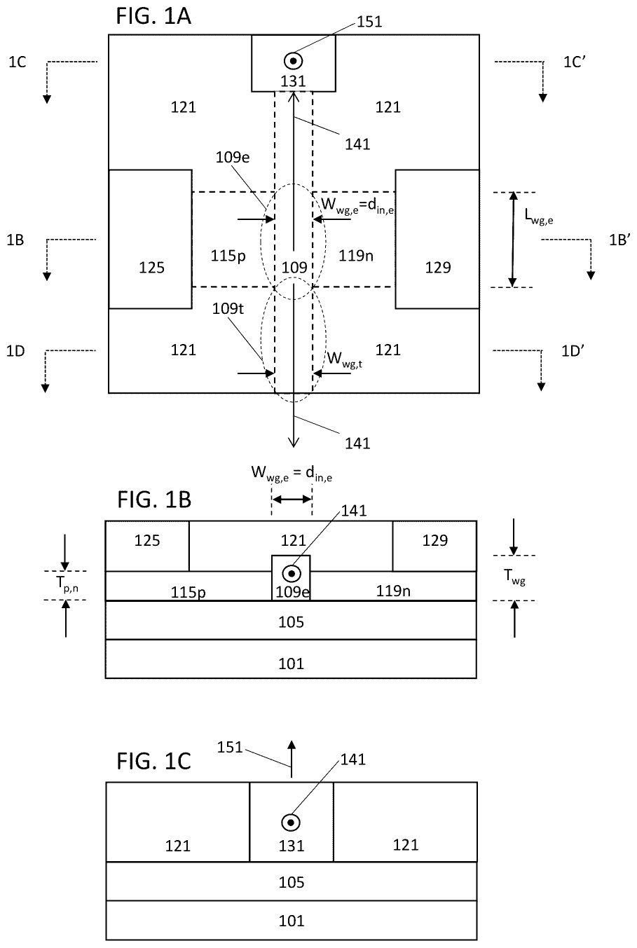

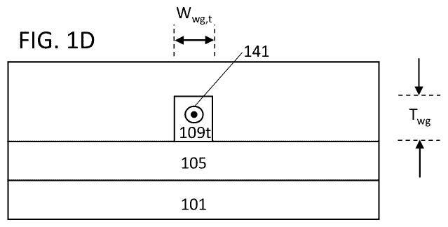

According to some embodiments illustrated in FIGS. 1A, 1B, 1C, and 1D, the broadband P-i-N waveguide radiation emitting diode is integrated into single-mode rib waveguide 109 on semiconductor substrate 101 (e.g., a silicon Si substrate), as shown in FIGS. 1A, 1B, 1C, and 1D. Waveguide 109 includes emitter portion 109e between p-type semiconductor layer 115p (e.g., p-type silicon layer) and n-type semiconductor layer 119n (e.g., n-type silicon layer), and emitter portion 109e may have an emitter width W_{wg,e}. Waveguide 109 also includes transmission portion 109t extending from emitter portion 109e having transmission width W_{wg,t}, where the widths W_{wg,e} and W_{wg,t} may be the same or different. In some embodiments, transmission portion 109t of single-mode rib waveguide 109 may have thickness T_{wg} of 220 nm, and transmission portion 109t of waveguide 109 can be fabricated either as a ridge (fully etched, with a width W_{wg,t} of 480 nm wide) or as a rib (half-etch, with a width W_{wg,t} of 550 nm wide) single-mode waveguide with silicon dioxide (SiO₂) top cladding layer 121 and SiO₂ bottom cladding layer 105. If a ridge waveguide is used for the transmission portion 109t, transmission portion 109t of the ridge waveguide (having width W_{wg,t} outside of the emission region) may adiabatically converts to a rib waveguide in emission portion 109e having width W_{wg,e}, and emission portion 109e may have a length L_{wg,e} of about 60 μm. As shown in FIGS. 1A, 1B, 1C, and 1D, the undoped emission portion 109e of rib waveguide 109 may be placed laterally between p-type (also referred to as p-doped) Si layer 115p and n-type (also referred to as n-doped) Si layer 119n. In addition, metal contact layers 125 and 129 may provide ohmic contact with respective p-type and n-type silicon layers 115p and 119n to provide charge injection and/or biasing the radiation emitting P-i-N diode.

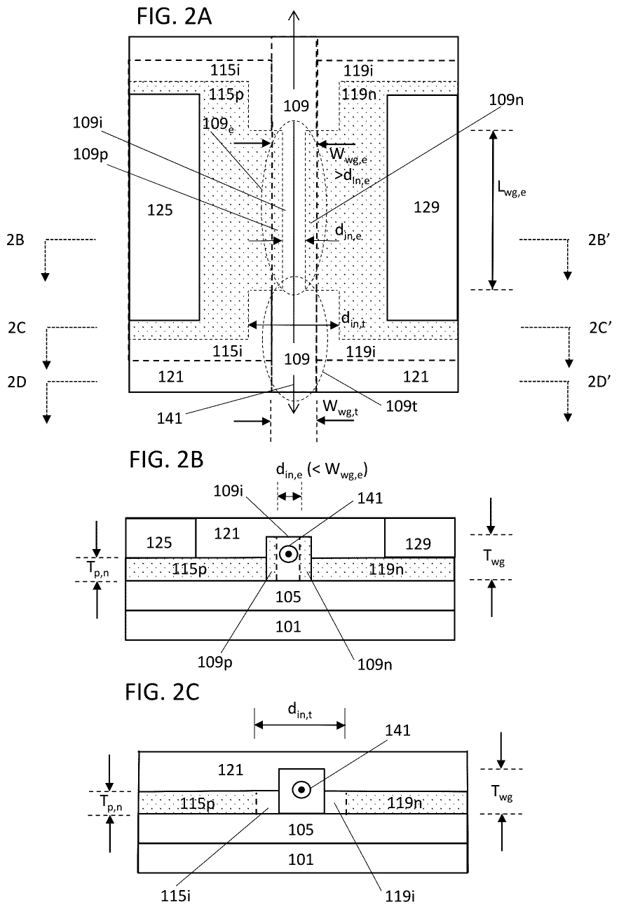

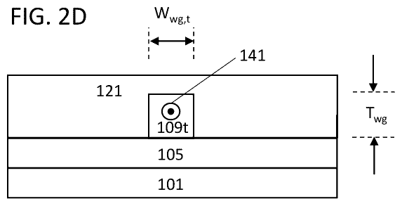

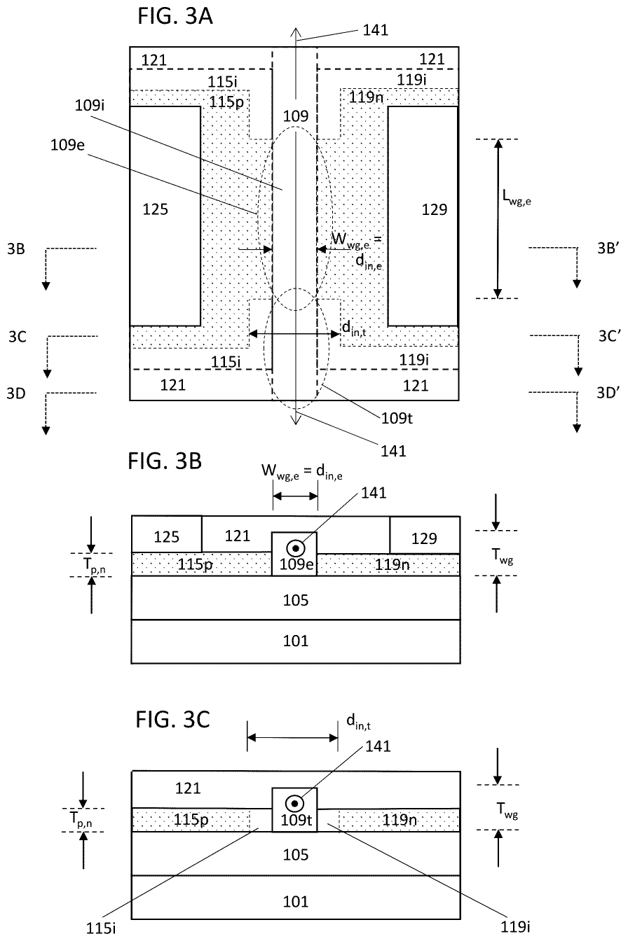

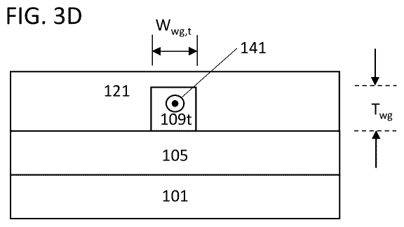

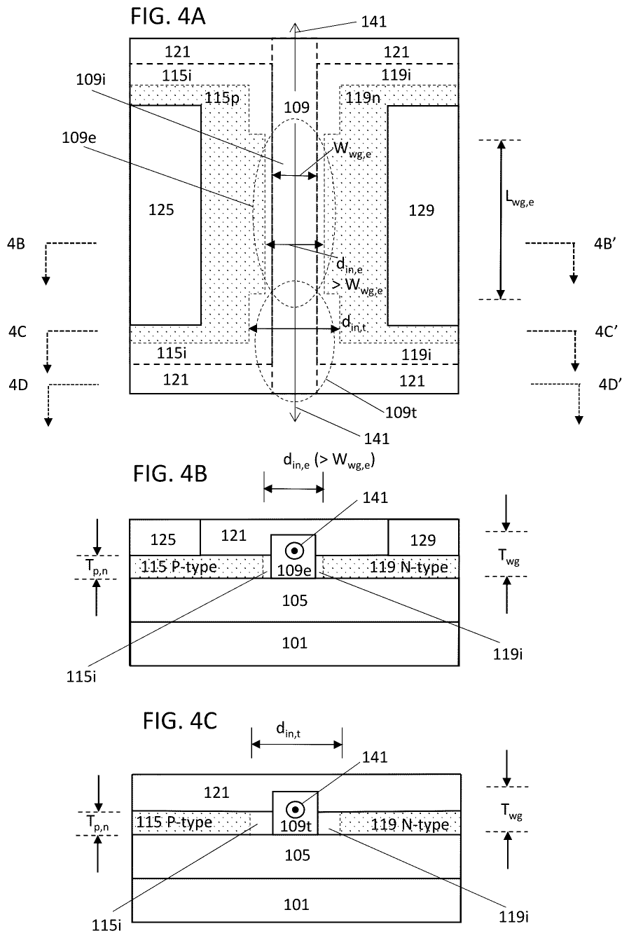

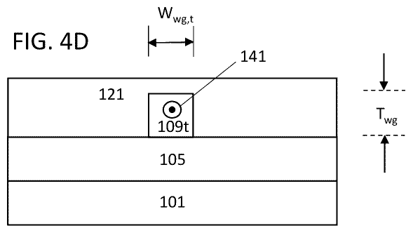

In embodiments of FIGS. 1A-D, a distance dine between p-type and n-type regions of the P-i-N radiation emitting diode may be equal to the width W_{wg,e} of emitter portion 109e of waveguide 109. According to other embodiments illustrated in FIGS. 2A-D, FIGS. 3A-D, and FIGS. 4A-D, distance dine between p-type and n-type regions of the P-i-N radiation emitting diode may be the same or different. The distance dine between p-type and n-type regions of the P-i-N radiation emitting diode (i.e., the width of the undoped/intrinsic gap between n-type and p-regions regions) may be, for example, 400 nm or 800 nm according to some embodiments of devices disclosed/investigated here.

Radiation (e.g., laser radiation) may thus be emitted by the P-i-N diode (defined by p-type layer 115p, waveguide emitting region 109e, and n-type layer 119n) through waveguide 109 in direction 141 that is parallel with respect to a surface of substrate 101. Waveguide 109 may be coupled with grating 131 such that grating 131 redirects the radiation in a direction 151 that is normal with respect to a surface of substrate 101.

As shown in FIGS. 1A and 1B, an emitting region 109e of waveguide 109 may be provided as a rib waveguide where a central portion of emitting region 109e has a full thickness/height T_{wg}, and where side portions of emitting region 109e (i.e., portions of layers 115p and 119n adjacent to the waveguide) have a reduced thickness/height T_{p,n}. Stated in other words, emitting region 109e of waveguide 109 may be defined as a rib waveguide including waveguide 109 and portions of layers 115p and 119n. As shown in FIGS. 1A and 1D, a transmitting region 109t of waveguide 109 may be provided as a ridge waveguide where vertical sidewalls of waveguide 109 run a full thickness of waveguide 109 in transmitting region 109t. Moreover, a width W_{wg,e} of emitting region 109e of waveguide 109 may be different (e.g., greater) than a width W_{wg,t} of transmission region 109t of waveguide 109.

In FIGS. 2A-D, 3A-D, and 4A-D, p-type semiconductor layer 115p may be provided in a semiconductor layer including doped p-type region/layer 115p and intrinsic undoped region/layer 115i, and n-type semiconductor layer 119n may be provided in a semiconductor layer including a doped n-type region/layer 119n and an intrinsic undoped region/layer 119i. In each of FIGS. 2A-D, 3A-D, and 4A-D, the semiconductor layers including p-type and n-type semiconductor layers 115p and 119n have a thickness T_{p,n}, and semiconductor waveguide 109 has a thickness T_{wg}. Moreover, emission region 109e of waveguide 109 (between p-type and n-type semiconductor layers 115p and 119n) has a width W_{wg,e} and a length L_{wg,e}, and transmission region 109t of waveguide 109 (spaced apart from p-type and n-type semiconductor layers 115p and 119n) has a width W_{wg,e}.

In FIGS. 2A-D, 3A-D, and 4A-D, at least a portion 109i of waveguide 109 in emission region 109e is intrinsic (i.e., undoped) so that p-type semiconductor layer 115p, intrinsic portion 109i, and n-type semiconductor layer 119n define a P-i-N radiation emitting diode. Moreover, distance dine between n-type and p-type regions of the P-i-N radiation emitting diode may be less than width W_{wg,e} of semiconductor waveguide (FIGS. 2A-D), distance dine between n-type and p-type regions of the P-i-N radiation emitting diode may be equal to width W_{wg,e} of semiconductor waveguide (FIGS. 3A-D), or distance d_{in,e} between n-type and p-type regions of the P-i-N radiation emitting diode may be greater than width W_{wg,e} of semiconductor waveguide (FIGS. 4A-D).

In FIGS. 2A-D, emission region 109e of semiconductor waveguide 109 includes p-type waveguide region 109p, intrinsic waveguide region 109i, and n-type waveguide region 109n. Accordingly, distance dine is defined by the distance between p-type and n-type waveguide regions 109p and 109n (or alternatively, a width of intrinsic waveguide region 109i). In this case, distance dine is less than the width W_{wg,e} of emission region 109e of semiconductor waveguide 109. In FIGS. 2A and 2B, portions of p-type semiconductor layer 115p, portions of n-type semiconductor layer 119n, and emission region 109e of waveguide 109 may define a rib waveguide as discussed above with respect to FIGS. 1A-D. In FIGS. 2A and 2D, transmission region 109t of waveguide 109 may define a ridge waveguide as discussed above with respect to FIGS. 1A-D. In FIGS. 3A-D, emission region 109e of semiconductor waveguide 109 includes intrinsic waveguide region 109i so that distance dine is defined by the width W_{wg,e} of emission region 109e of semiconductor waveguide 109. In this case, distance dine is equal to the width W_{wg,e} of emission region 109e of semiconductor waveguide 109. In FIGS. 3A and 3B, portions of p-type semiconductor layer 115p, portions of n-type semiconductor layer 119n, and emission region 109e of waveguide 109 may define a rib waveguide as discussed above with respect to FIGS. 1A-D. In FIGS. 3A and 3D, transmission region 109t of waveguide 109 may define a ridge waveguide as discussed above with respect to FIGS. 1A-D.

In FIGS. 4A-D, emission region 109e of semiconductor waveguide 109 includes intrinsic waveguide region 109i (over a full width of waveguide 109 in emission region 109e). In addition, a portion of intrinsic semiconductor layer 115i is provided between p-type semiconductor layer 115p and waveguide 109, and a portion of intrinsic semiconductor layer 119i is provided between n-type semiconductor layer 119n and waveguide 109. In this case, distance dine is defined by the distance between p-type and n-type semiconductor layers 115p and 119n (including portions of intrinsic semiconductor layer 115i, waveguide 109, and portions of intrinsic semiconductor layer 119i). In FIGS. 4A and 4B, portions of p-type/intrinsic semiconductor layers 115p/115i, portions of n-type/intrinsic semiconductor layers 119n/119i, and emission region 109e of waveguide 109 may define a rib waveguide as discussed above with respect to FIGS. 1A-D. In FIGS. 4A and 4D, transmission region 109t of waveguide 109 may define a ridge waveguide as discussed above with respect to FIGS. 1A-D.

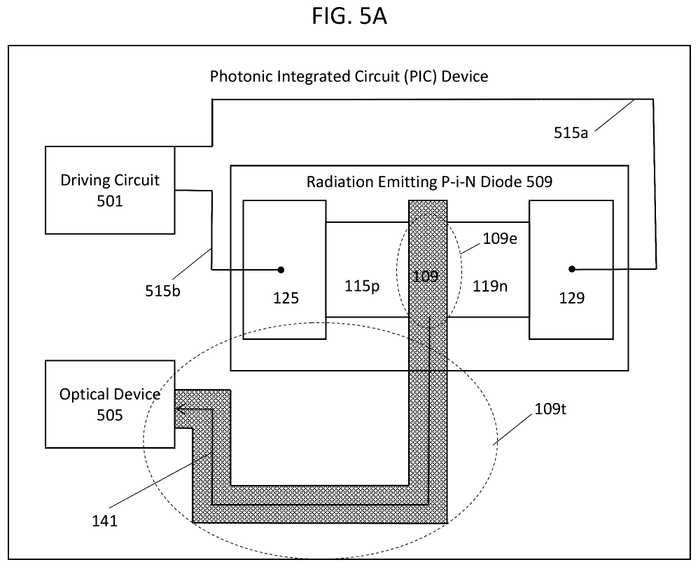

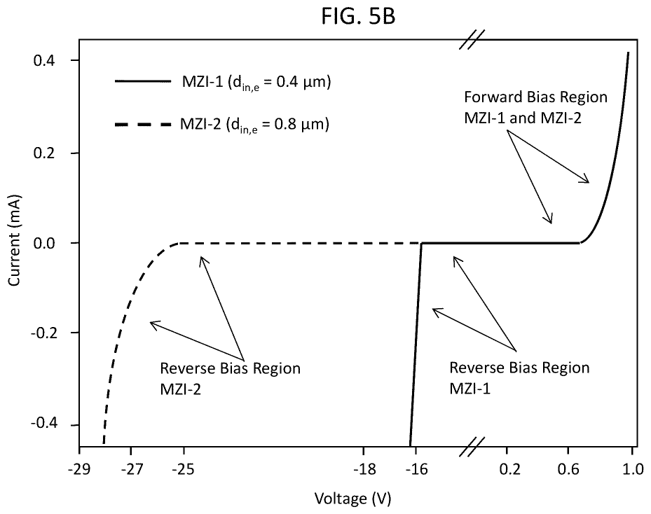

FIG. 5A is a schematic representation of a Photonic Integrated Circuit (PIC) device including driving circuit 501, optical device 505, and radiation emitting P-i-N diode 509 according to some embodiments of inventive concepts. Each of driving circuit 501, optical device 505, and radiation emitting P-i-N diode 509 may be provided on a same semiconductor substrate (e.g., semiconductor substrate 101) such as a semiconductor silicon substrate, and P-i-N diode 509 and/or waveguide 109 may be provided as discussed above with respect to any of FIGS. 1A-D, 2A-D, 3A-D, and/or 4A-D. Driving circuit 501, for example, may include one or more N-channel metal oxide semiconductor (NMOS) transistors and/or P-channel metal oxide semiconductor (PMOS) transistors fabricated in/on semiconductor substrate 101.

Driving circuit 501 is electrically coupled with p-type semiconductor layer 115p and n-type semiconductor layer 119n (e.g., via conductive traces 515a and 515b), with the radiation emitting P-i-N diode being configured to emit radiation responsive to an electrical signal applied across the p-type and the n-type semiconductor layers 115p and 119n. According to some embodiments, driving circuit 501 is configured to apply a reverse bias electrical signal across the p-type and n-type semiconductor layers 115p and 119n, and radiation emitting P-i-N diode 509 is configured to emit the radiation responsive to the reverse bias electrical signal. According to some other embodiments, driving circuit 501 is configured to apply a forward bias electrical signal across p-type and n-type semiconductor layers 115p and 119n, and radiation emitting P-i-N diode 509 is configured to emit the radiation responsive to the reverse bias electrical signal. Forward and reverse bias operations are discussed below with respect to the graph of FIG. 5B.

Optical device 505 may include one or more of: a grating (configured to redirect a direction of emissions from a direction 141 parallel with a surface of the substrate to a direction 151 that is normal with respect to a surface of the substrate); a photodiode (configured to receive at least a portion of the radiation emitted from the radiation emitting diode through the semiconductor waveguide); a spectrometer (configured to receive at least a portion of the radiation emitted from the radiation emitting diode through the semiconductor waveguide); a spectral filter (configured to filter at least a portion of the radiation emitted from the radiation emitting diode through the semiconductor waveguide); and/or a spiral waveguide (configured to receive at least a portion of the radiation emitted from the radiation emitting diode through the semiconductor waveguide).

According to some embodiments, Optical device 505 may be a spectral filter including one or more of a Mach-Zehnder interferometer, a lattice filter, a Fabry-Perot cavity, a microring resonator cavity, a photonic crystal cavity, a directional coupler, and/or any other integrated photonic component with a wavelength-dependent response.

According to some other embodiments optical device 505 may include a spiral waveguide optically coupled with radiation emitting diode 509, a dielectric cladding layer on the semiconductor waveguide, and a sensor coupled with the spiral waveguide. The semiconductor waveguide is between the dielectric cladding layer and the substrate, a sensing portions of the spiral waveguide is free of the dielectric cladding layer, and the sensing portion of the spiral waveguide is configured to receive a chemical analyte (e.g., water, isopropyl alcohol, etc.). The sensor is configured to determine a property of the chemical analyte based on a change in an absorption spectrum of the radiation received by the spiral waveguide from the radiation emitting diode.

FIG. 5B is a graph illustrating current-voltage (I-V) operating characteristics of a radiation emitting diode/waveguide of FIGS. 2A-D (with d_{in,e}<W_{wg,e}, referred to as MZI-1) and operating characteristics of a radiation emitting diode/waveguide of FIGS. 4A-D (with d_{in,e}>W_{wg,e}, referred to as MZI-2). In FIG. 5B, room temperature I-V characteristics of p-i-n diodes/waveguides are graphed. The graph of MZI-1 (solid line) is provided for the P-i-N radiation emitting diode of FIGS. 2A-D with d_{in,e}=400 nm, W_{wg,e}=550 nm, T_{p,n}=110 nm, and T_{wg}=220 nm. The graph of MZI-2 (dashed line) is provided for the P-i-N radiation emitting diode of FIGS. 4A-C with d_{in,e}=800 nm, W_{wg,e}=550 nm, T_{p,n}=110 nm, and T_{wg}=220 nm. Where the two graphs overlap (for voltages greater than about-15 volts including forward bias operation), the overlapping graphs are shown as a solid line.

The forward bias turn-on voltage for both MZI-1 and MZI-2 is approximately 0.7 V, and the reverse-bias breakdown voltages are −16 V for MZI-1 (d_{in,e}=400 nm) and −28 V for MZI-2 (d_{in,e}=800 nm). Surface-normal infrared (IR) imaging of P-i-N rib waveguides of MZI-1 and MZI-2 shows that the devices emit light for both forward-bias and reverse-bias operation. This light also couples to the modes of the rib waveguide, propagates down the ridge waveguide, and is then emitted surface-normal from a grating (at one end of the waveguide) and from a cleaved waveguide facet (at the other end). The forward-bias emission from the grating appears to be emitted from a narrow spot, indicating a relatively narrow-band emission spectrum. When applying reverse-bias, however, a broadened grating emission pattern is observed. The angle of grating emission is largely wavelength dependent, so that a broad emission pattern suggests that many wavelengths are being coupled out of the grating. Wavelength dependence of the angle of grating emission is further discussed in the section of U.S. Provisional Application No. 63/500,359 entitled “Supplementary Information: Broadband Near-Infrared Emission in Silicon Waveguides,” the disclosure of which is hereby incorporated herein in its entirety by reference, and is referred to herein as “Supplementary Information.” Looking at the P-i-N diode region, the emission profile appears highly-concentrated to the 400 nm wide intrinsic region for reverse bias for MZI-1 while the emission profile is much more spatially-broadened in forward bias. As further discussed below, infrared (IR) images suggest distinct physical mechanisms for the emission depending on the bias point.

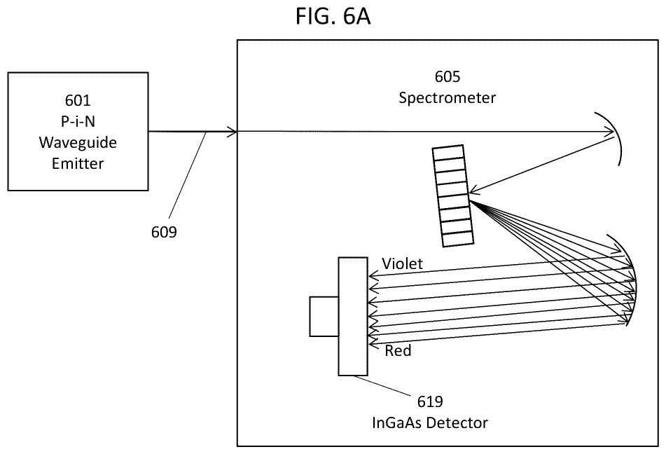

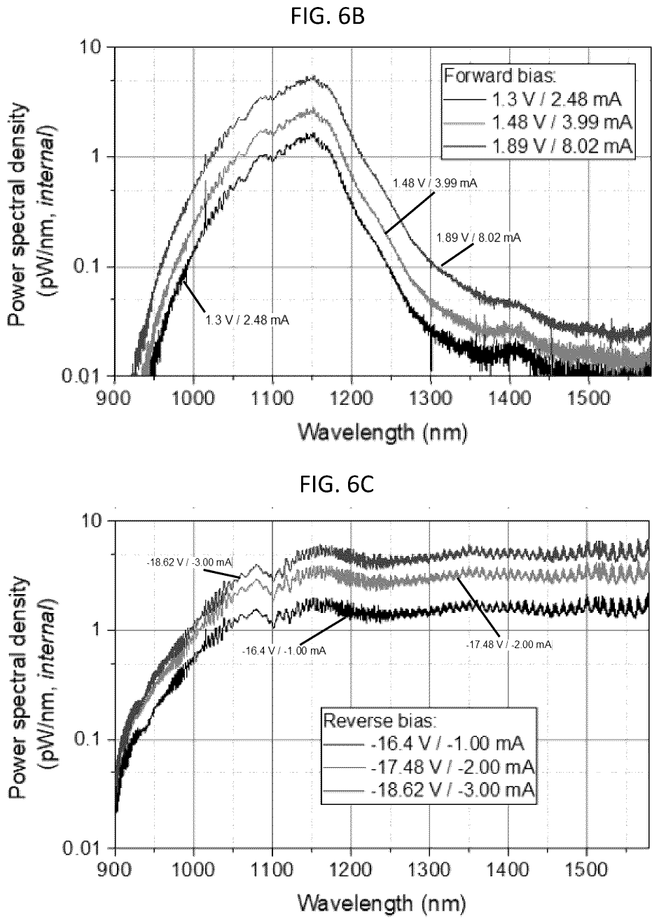

Quantitative measurements of the emission spectrum were performed using a setup illustrated in FIG. 6A including radiation emitting P-i-N waveguide emitter 601 and spectrometer 605. Radiation emitting P-i-N waveguide emitter 601 may be provided as discussed above with respect to any of FIGS. 1A-D, 2A-D, 3A-D, and/or 4A-D. First, broadband emission generated by the p-i-n waveguide emitter 601 couples to a lensed polarization-maintaining (PM) fiber 609 (e.g., Oz Optics TPMJ) via a cleaved waveguide facet. The fiber slow axis is aligned parallel to the sample plane. Cleaved facets may be preferable relative to grating couplers because the latter may have a relatively narrow spectral response (e.g., FWHM=30 nm, see “Supplementary Information”), and the former can efficiently couple light over hundreds of nanometers. The light travels via PM fiber 609 to a 0.5-meter Czerny-Turner grating spectrometer 605 (e.g., Princeton Instruments SP2558) with a liquid nitrogen-cooled InGaAs detector 619. The calculated fiber-facet coupling (see, “Supplementary Information”), the spectrometer grating, and the detector efficiency curves were used to extract the absolute (internal) power in the waveguide. The measured power spectra from the edge facet confirms narrowband emission near silicon's bandedge (1.1 eV) for forward bias in a P-i-N diode with a 400 nm wide intrinsic regions (as discussed above with respect to device MZI-1 of FIG. 5B) is shown in the graph of FIG. 6B. The measured power spectra from the edge facet confirms broadband emission for reverse-bias, in a P-i-N diode with a 400 nm wide intrinsic region (as discussed above with respect to device MZI-1 of FIG. 5B) as shown in the graph of FIG. 6C. Both sets of spectra may be limited by absorption in the silicon waveguide (wavelengths less than 1100 nm) between the emitter and the edge facet and by the spectrometer used (with a detection range between 900 nm and 1580 nm). As will be discussed, the reverse-bias emission likely extends far beyond 1580 nm in wavelength shown in FIG. 6B.

After an initial voltage sweep, the emission was found to be very stable in time and wavelength. Tests for 98 hours of continuous operation show little/no significant degradation in the emitter power, little/no significant change in the I-V characteristic, and little/no significant change to the spectral characteristics (see, “Supplementary Information”). Similar power spectral density for an 800 nm wide intrinsic region was also obtained, as expected since both intrinsic regions have similar modal overlaps between the TE₀₀ mode and the emitter (see, “Supplementary Information” and discussion below).

Emission Mechanisms are discussed below.

Surface-normal emission of light from biased P-(i)-N junctions in silicon has been previously observed (see, References [5], [9], [10], and [25]). Silicon's indirect bandgap reduces/prevents direct electron-hole recombination at the band edge, but a number of other mechanisms may nevertheless allow for optical emission by injected carriers, albeit at lower quantum efficiency. For forward-bias, injected carriers in the depletion region can recombine with the aid of phonons (see, “Supplementary Information”) to produce emission that peaks at the bandedge (see, References [5] and [8]) (1.1 eV). In a waveguide, this emission is then filtered by absorption in the silicon between the emission region and the collection fiber. As shown in the forward-bias measurements in FIG. 6B, this results in a peak waveguide emission that is to the red of the silicon band edge. Forward-bias emission should then occur where ever injected current passes through the intrinsic region, which has been observed in a surface-normal “hourglass” emission profile from the P-i-N emission region.

For the reverse-bias emission spectra shown in FIG. 6C, the larger field in the intrinsic region accelerates injected electrons and holes to energies sufficient for impact ionization. Unlike the forward-bias spectra, these extreme field (>400 kV/cm) spectra show broadband emission spanning the wavelength range of the detector that was used. Such low energy emission cannot be explained by interband recombination, but instead is believed to arise from intraband processes. It is expected that this intraband emission will extend to the visible, for example, to energies as high as the ionization energy, ˜2.3 eV, (see, References [5], [10], and [25]), but, as with the forward-bias spectra, at energies above the silicon bandedge any emission may be absorbed by the silicon waveguide. For reverse-bias, hot electrons (holes) in the silicon conduction (valence) band may emit infrared photons via an intraband blackbody process.

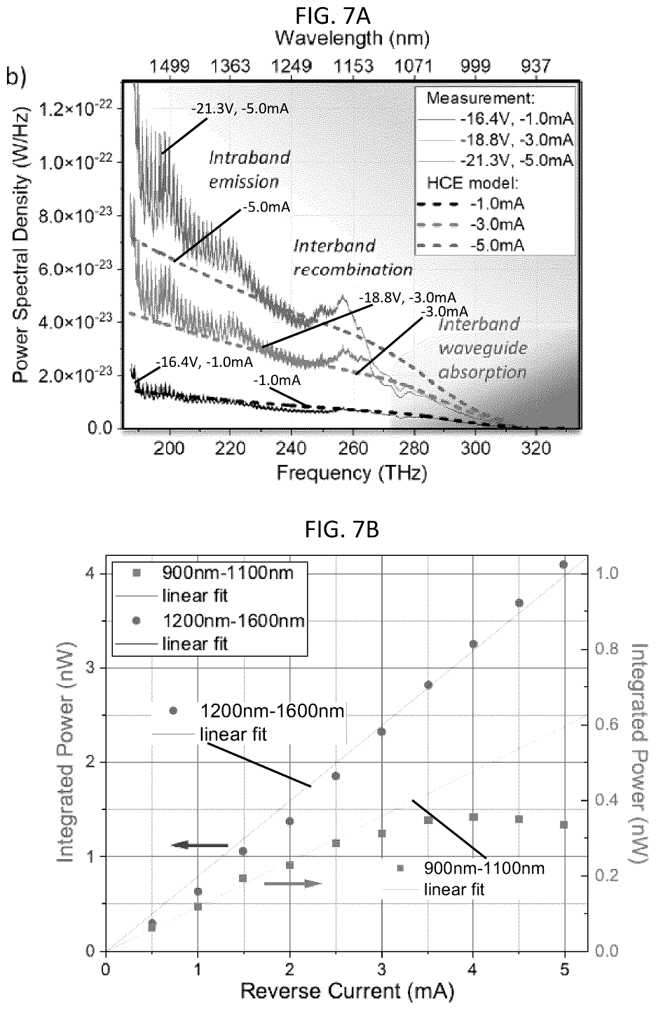

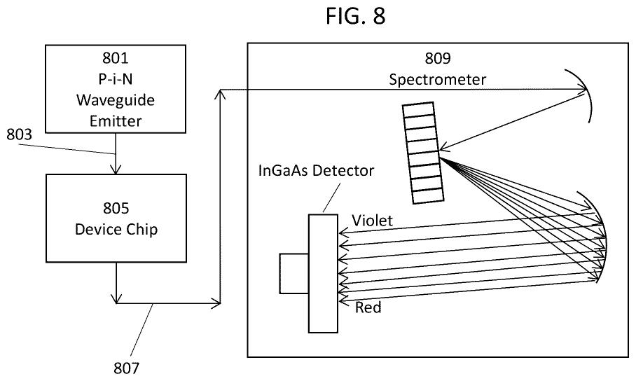

The graph of FIG. 7A illustrates measured reverse-bias waveguide power spectral density plotted vs. optical frequency for-16.4 V and −1.0 mA, for −18.8 V and −3.0 mA, and for −21.3 V and −5.0 mA. Equation 4 is also plotted as the Hot-Carrier-Emission (HCE) model for a carrier temperature of 9000 K (at −1.0 mA, at −3.0 mA, and at −5.0 mA), scaled by the silicon waveguide absorption between the emitter and the facet.

Broadband intraband emission from hot carriers in silicon can arise from a number of phenomena, including bremsstrahlung radiation, direct intraband transitions (between nearly degenerate conduction bands or valence bands), and/or indirect transitions within a single band. Previous observations of reverse-bias emission in surface-normal geometries in the visible have rejected bremsstrahlung emission as a primary mechanism due to its energy dependence (see, References [25], [26], and [27]), though they allow for some contribution at higher photon energies (>2 eV). Direct intraband transitions could occur near the X-point for conduction band electrons or near the Γ-point for valence holes. Since these transitions, however, may be strictly forbidden at the X-point and the Γ-point, the amplitude of this radiation would be expected to increase with photon energy as the transition probability increases with the band separation. That trend is the opposite of what is observed, as shown in FIG. 7A.

Indirect intraband photon emission could arise from either holes, electrons, or a combination of both, and may require carrier scattering from phonons or material defects to conserve momentum. The hot carriers are typically assumed to be in a nonequilibrium state with the lattice (see, References [10], [25], and [26]). To estimate the emitted power spectral density in the waveguide mode, it is assumed that the hot-carrier plasma must be in thermal equilibrium with the modes of the electromagnetic field (see, Reference [28]). The Planck distribution combined with a one-dimensional (waveguide) density of states is the resulting power spectral density for a single mode and propagation direction (see, Reference [29]):

$$P ( \text{?} ) = \frac{h \text{?}}{\text{?} - 1} ; \qquad Equation ( 1 )$$

$$\text{?} \text{indicates text missing or illegible when filed}$$

where v is the frequency of the optical radiation and T_{e,h} is the hot carrier temperature (for electrons or holes). Note that the frequency dependence of Equation 1 only depends on V in the numerator, unlike the conventional (3-dimensional) Planck radiation law, which depends on v³ (see, Reference [29]).

Emissivity of the hot carrier plasma can be estimated from its absorptivity, using Kirchoff's law, and uses free-carrier absorption relationships to find the absorptivity (see, Reference [30]):

$$\text{?} ( v ) = \frac{{K}_{e , h} {N}_{e , h} \text{?}}{{v}^{2}} ; \qquad Equation ( 2 )$$

$$\text{?} \text{indicates text missing or illegible when filed}$$

where Kₑ=1×10⁻¹⁰ for electrons, Kₕ=2.7×10⁻¹⁰ for holes, and N_{e,h} is the carrier concentration.

The carrier concentration can be approximated with the diode current and geometry:

$${N}_{e , h} = \frac{I}{\text{?} {L}_{em} {t}_{em}} ; \qquad Equation ( 3 )$$

$$\text{?} \text{indicates text missing or illegible when filed}$$

where/is the reverse current, vₛₐₜ is the saturation velocity of the electrons or holes (˜1×10⁵ m/s in silicon, see, Reference [31]), and Lₑₘ and tₑₘ are the length and thickness of the emitter.

Assuming an emissivity ϵ(v) equal to α(V) LₑₘΓ(v)n_{g}(v)/n_{g}^{Si}(v), where Γ is the modal confinement factor within the intrinsic (emitter) region, n_{g} is the waveguide mode group index, and n_{g}^{Si} is the group index of silicon (see, “Supplementary Information”), this model gives an emissivity-corrected power spectral density of:

$$P ( v ) \text{?} ( v ) = \frac{I \text{?}}{\text{?}} \frac{\text{?} ( v ) {n}_{g} ( v )}{{n}_{g}^{Si} ( v )} ( \frac{K \text{?}}{\text{?} - 1 )} + \frac{K \text{?}}{\text{?} - 1 )} ) ; \qquad Equation ( 4 )$$

$$\text{?} \text{indicates text missing or illegible when filed}$$

assuming an equal density of electrons and holes. Note that this discussion applies to only a single electromagnetic mode of the waveguide, but both the TE₀₀ and TE₁₀ modes are supported by the rib below 1400 nm, as well as the TM₀₀ at wavelengths below 1050 nm (see “Supplementary Information”). Since the even Gaussian modes of the collection fiber mostly filter out the odd TE₁₀ mode, it is believed that that mode is not present in the measured spectra herein and is thus ignored in the analysis. The TM₀₀ mode is collected, but at levels significantly attenuated due to bandedge absorption.

This hot-carrier-emission (HCE) model has only two free parameters, the hot-hole and hot-electron temperatures. The measured power spectral density in FIG. 7A agrees well with the predicted power-spectral density from this model using a value of 9000 K for the carrier temperature, as shown in FIG. 7A. The HCE spectrum also includes the waveguide absorption near the band edge to account for propagation losses between the emitter and the waveguide facet. It is likely that the actual hole and electron temperatures may differ somewhat from each other due to variations in effective mass and saturation velocity. Though 9000 K is warmer than is typically surmised for hot carriers, this would correspond to a carrier energy of only 0.78 eV, consistent with Monte Carlo models of carriers in high fields (see, Reference [31]). A carrier energy of 0.78 eV is also approaching the bandgap of silicon, which is a necessary condition to begin reverse breakdown of the diode. An estimated hot-carrier temperature herein is also sensitive to uncertainties in other estimated parameters. For example, if either the free-carrier absorption or spectrometer intensity calibration were in error by a factor of two, the extracted carrier temperature could be closer to 5000 K. Despite these uncertainties, the HCE model shows excellent agreement with both the spectral shape and intensity of the emission as shown in FIG. 7A. In addition, this model predicts similar powers from devices with a diode intrinsic region width that varies between 400 nm and 800 nm, which is largely consistent with measurements (see, “Supplementary Information”).

Intraband hot-carrier emission would be expected to arise only from regions of the diode with a field sufficient to accelerate carriers to their saturation velocities. Thus, unlike the forward-bias case, reverse-bias based intraband HCE should only occur in the depleted regions of the diode with the narrowest gap (highest field) between the anode and the cathode. This surface-normal emission profile has been observed.

The integrated power measured over the detection range of the spectrometer (up to 1580 nm wavelength) is 5.1 nW at 5 mA reverse bias current, corresponding to a measured efficiency of approximately 1×10⁻⁶ W/A. Higher emitter powers can be important to obtain higher intensities at specific wavelengths of interest, lower-noise spectra, and/or spectra obtained with shorter integration times. As Equation 4 shows, more current can be injected into the diode to increase the emissivity of the device. The calculated absorptivity (αL) in this wavelength range for 5 mA is approximately 1×10⁻³, suggesting 1000× more emitted power is possible with higher reverse currents. Unfortunately, finite-element models of lattice heating due to resistive heating indicate that the local lattice temperature at the emitter rises by 250 K for electrical powers of 100 mW (see, “Supplementary Information”) corresponding to reverse-bias current of 5 mA. Thus, thermal failure at the diode may pose the ultimate limit to the achievable emitted power.

FIG. 7B is a graph illustrating measured power vs. reverse current for two wavelength ranges, as well as a linear fit to the reverse-bias currents <2.5 mA. Saturation of the emissivity can already be observed at 4 mA for wavelengths near the silicon bandedge (900 nm to 1100 nm), as shown in the graph of FIG. 7B, presumably since here the device has become effectively opaque (and is made only more so as the bandedge redshifts with Joule heating). At longer wavelengths (1200 nm to 1600 nm), little/no such saturation is observed at currents up to 5 mA, consistent with an emissivity limited by free-carrier absorption. The measured internal intensity of the emitter, 4100 mW/cm² at 5 mA, is already an order-of-magnitude larger than the previously reported record value for a silicon emitter, 600 mW/cm² (see, Reference [32]).

The waveguide hot-carrier emission may be limited at short wavelengths by silicon band edge absorption, and at long wavelengths by technical losses such as substrate leakage, bend loss, or material absorption. For the rib waveguides considered in the present disclosure, transmission out to wavelengths of beyond 3.0 μm may be possible (see, “Supplementary Information”). Such a broadband waveguide source that operates in the near- and mid-wave infrared is immediately applicable to chip-scale spectroscopy for sensing and device characterization.

Integrated device characterization is discussed below.

The nanowatts of broadband hot-carrier emission in a single-mode silicon waveguide can be used for on-chip characterization of integrated photonic components without the need for an off-chip tunable laser or broadband source. To demonstrate this, light from a silicon P-i-N waveguide emitter 801 (according to embodiments disclosed herein) was coupled to a PM optical fiber 803 that was connected to a second PIC device chip 805 that was also fabricated at AIM Photonics as shown in the measurement setup of FIG. 8. Moreover, P-i-N waveguide emitter 801 and device chip 805 were fabricated using the same process flow and fabrication tools (such that the two could be fabricated on the same PIC substrate). This second PIC chip 805 has various broadband integrated photonic components, which could be fabricated in the same PIC as the silicon emitter 801, for example, as shown by diode 509 and optical device 505 of FIG. 5A. Two optical devices were measured (as optical devices of device chip 805) using spectrometer 809: unbalanced Mach-Zehnder interferometers (MZIs) with different path length imbalances; and a lattice filter (see, Reference [33]). The output from the second PIC 805 is sent via PM fiber 807 to spectrometer 809, which may be the same as spectrometer 60 discussed above with respect to FIG. 6A.

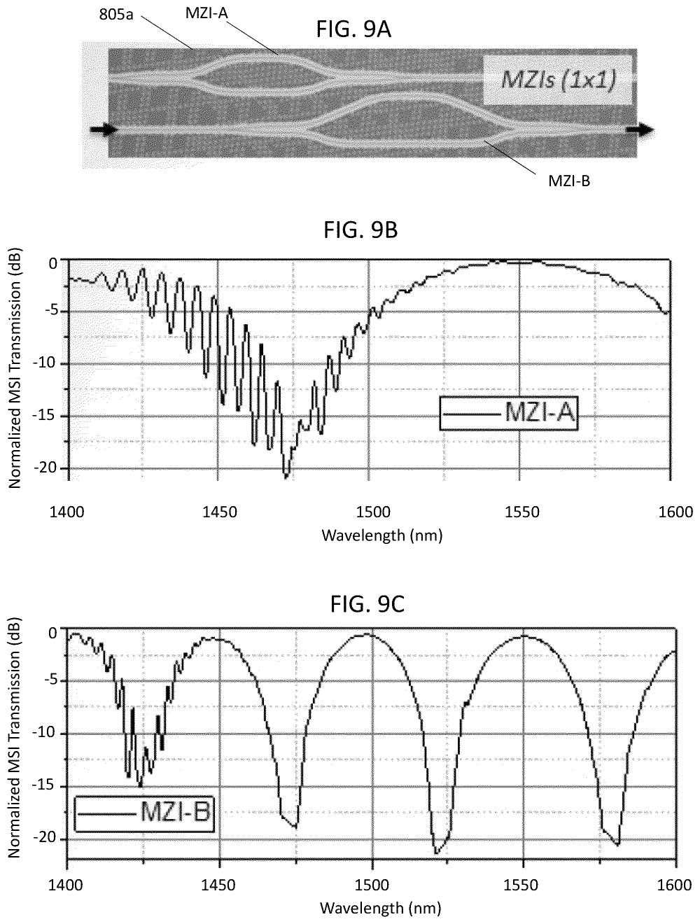

The MZIs are single-input/output devices (1×1 MZIs) as shown in FIG. 9A designed for operation in the S/C/L bands. The MZIs comprise silicon nitride waveguides MZI-A and MZI-B that are 220 nm thick and 1500 nm wide. Input light splits, via a waveguide y-splitter, into two separate, unbalanced waveguide paths. The two paths recombine, resulting in an interference spectrum determined by the path length imbalance of the two arms. Measurements discussed herein span a wavelength range from 1400 to 1600 nm, which may be difficult to achieve in a single off-chip tunable laser system, and, until this work, may be difficult or impossible to achieve with an on-chip source. The measurements illustrated in the graphs of FIGS. 9B and 9C were taken using a broadband light source from waveguide emitter 801. The measurements in FIGS. 9B and 9C respectively show interference spectra from the two devices MZI-A and MZI-B provided on device chip 805a, where MZI-B has a path length imbalance three times that of MZI-A resulting in an increase in the interference order. MZIs have become important/critical PIC components for in-situ material process characterization and statistical analysis to track wafer-scale variability of photonic geometries and indices (see, References and [35]). The spectra also exhibit a high-frequency oscillation at short wavelengths that is attributed to beating between the TE₀₀ and TE₁₀ modes (see, “Supplementary Information”).

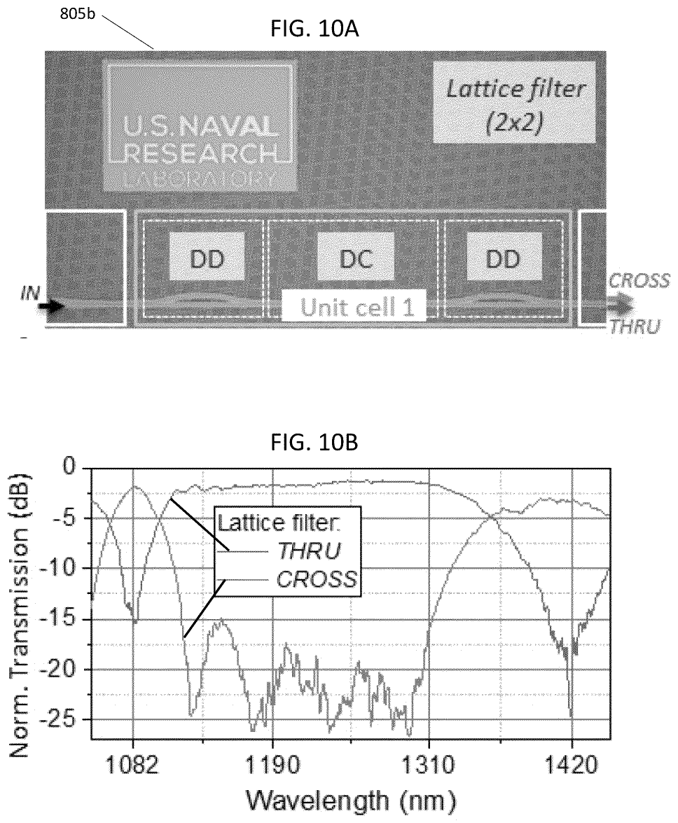

A second photonic component that was characterized is a four-port (2×2) lattice filter (see, Reference [33]) is shown on device chip 805b of FIG. 10A with a unit cell including two different delays (DD) and one broadband directional coupler (DC). This filter enables large passbands with narrow rejection bands and may be useful, for example, to filter out the laser pump signal in waveguide-enhanced Raman spectroscopy (WERS) (see, Reference [36]) or flourescence spectroscopy. The filter response is determined from cascaded unit cells, each of which includes a differential delay (DD) and a broadband directional coupler (DC) section as shown in FIG. 10A. This particular device of FIG. 10A was designed to reject (pass) a laser at 1064 nm and pass (reject) light at longer wavelengths in the thru (cross) port. FIG. 10B is a graph illustrating a measured lattice filter response from the lattice filter of FIG. 10A, where the measured spectra span a wavelength range from 1050 nm to 1450 nm and confirm a large passband of 180 nm with relatively narrow rejection bands centered at 1082 nm and 1420 nm (thru port 1 in FIG. 10B). Broadband characterization of fabricated lattice filters is critical before insertion into PIC systems to insure that component performance meets design criteria.

As demonstrated by the measurements in FIGS. 9B-C and 10B, the reverse-bias emission from silicon diode optical sources of the present disclosure may be sufficient for high-fidelity photonic device and waveguide characterization, as well as mode cutoff determination. Even higher extinction ratios and signal levels may be possible by integrating the source and components on the same PIC, reducing/avoiding multiple fiber-to waveguide coupling losses. According to some embodiments of inventive concepts, the wavelength range of the on-chip broadband source may exceed that of off-chip tunable laser sources or LEDs and may thus offer unique capabilities for in-situ integrated photonic device characterization.

Liquid-phase analyte sensing is discussed below.

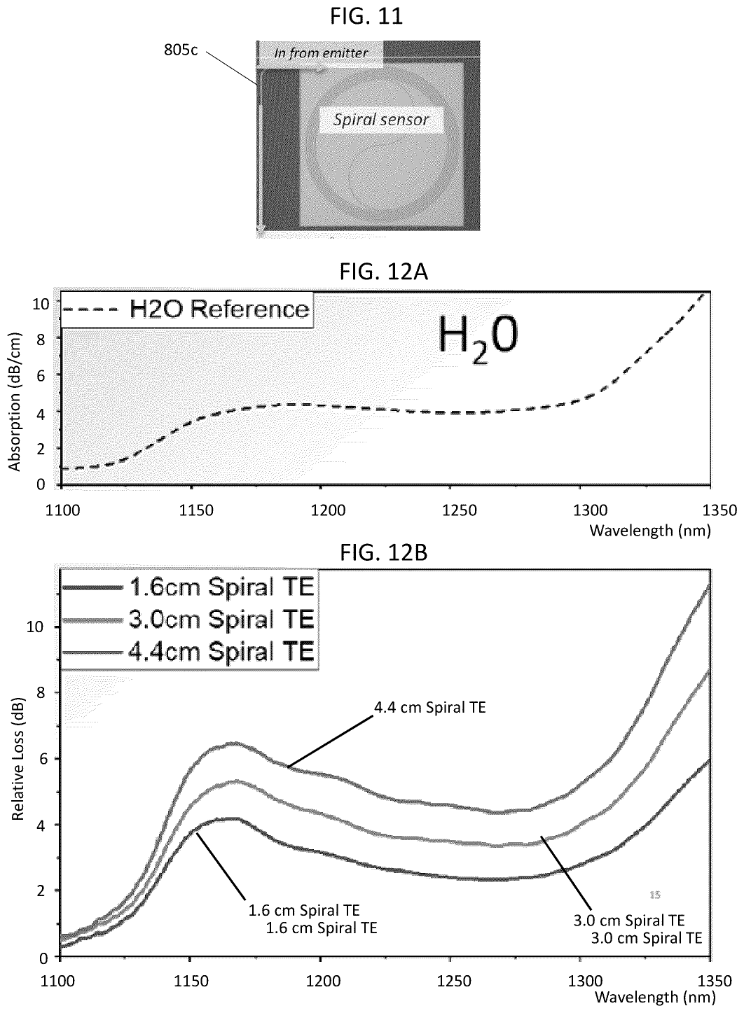

Waveguide emitters according to some embodiments of inventive concepts may also be used to enable absorption spectroscopy for chemical sensing via waveguide infrared absorption spectroscopy (WIRAS) (see, Reference regarding spectroscopy). FIG. 11A illustrates a WIRAS setup including a spiral sensor on a device chip 805c. Similar to the component characterization discussed above with respect to FIG. 8, the silicon emitter 801 may be coupled via PM fiber 803 to a silicon nitride sensing chip 805c (provided as device chip 805 of FIG. 8), which could be fabricated on the same PIC as the silicon emitter as discussed above with respect to FIG. 5A. WIRAS uses/requires a single-mode, low-loss waveguide with a sensing trench to expose the waveguide optical mode to the liquid analyte. The trench region (the square in the spiral waveguide sensor in FIG. 11A) has the top SiO₂ cladding removed to enable access to the propagating mode's evanescent field. The waveguides used here include a bottom thermal SiO₂, a 220 nm SiN waveguide layer patterned into 0.8 μm-wide Archimedes spirals, and a top SiO₂ cladding (removed in the sensing trench). The IR light transmitted through the sensing spiral is collected with a second polarization maintaining (PM) fiber and sent to spectrometer 809.

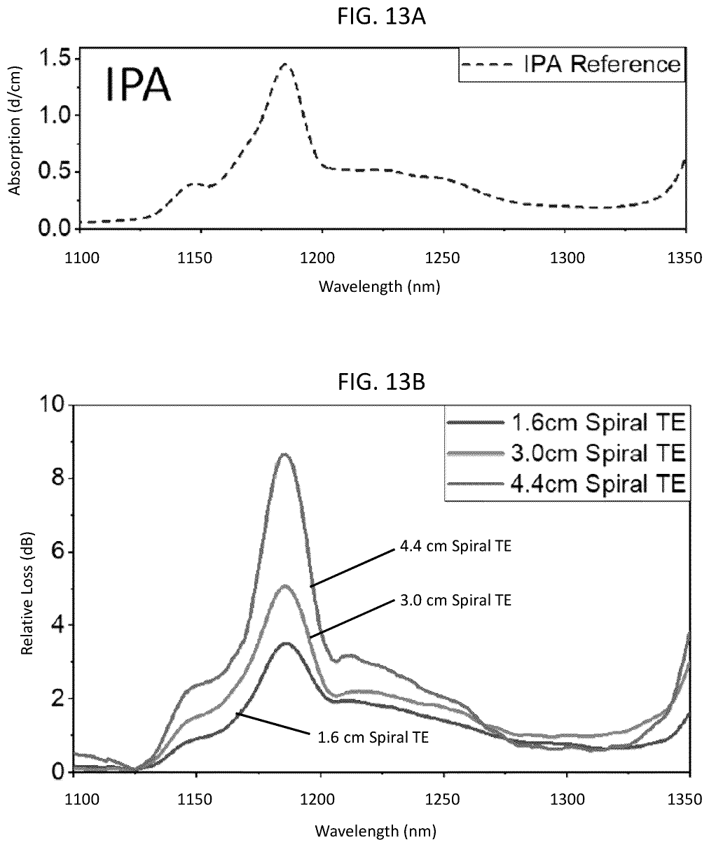

Two liquid analytes served as proof of principle for this work: water (H₂O) and isopropyl alcohol (IPA). For each analyte, a drop was pipetted onto the spiral waveguide of FIG. 11. Transmission through three different lengths of spiral waveguide was measured with the transmission spectra being modified by the presence of the liquid analyte. The measured WIRAS spectra from H₂O is illustrated in the graphs of FIGS. 12A and 12B, and the measured WIRAS spectra from IPA is illustrated in the graphs of FIGS. 13A and 13B, along with reference spectra (see, references [37] and [38]). The measured spectra are normalized and, as expected, the absorption increases with the spiral length. The measured data agrees very well with the reference spectra, enabling clear identification of both analytes. These measurements confirm that the near-Infrared (NIR) light from the silicon waveguide emitter of the present disclosure is more than adequate to perform WIRAS on common liquid analytes and demonstrates the practical utility of waveguide-integrated silicon light sources of the present disclosure for chip-scale sensing applications.

Although the spectroscopy demonstrations discussed above with respect to FIGS. 11, 12A-B, and 13A-B used an off-chip spectrometer, efforts are underway to develop chip-scale spectrometers (see, References [19, 39-41]) fabricated in silicon and silicon nitride waveguide platforms. It is also important to note that compact, uncooled, and/or thermoelectrically-cooled spectrometers are now available with performances that are very similar to those of benchtop liquid-nitrogen cooled systems (see, Reference [42]). In fact, measurements of the reverse-bias HCE spectra with a handheld spectrometer (Wasatch Photonics NIR1) show nearly identical signal and signal-to-noise as that obtained in the benchtop system described above (see, “Supplementary Information”).

As disclosed herein, a broadband infrared silicon light source fabricated in a 300-mm CMOS PIC foundry (AIM Photonics) has been experimentally demonstrated and integrated into a single-mode waveguide. The emission is described using a new theoretical framework that combines Planck radiation in one dimension with hot carriers in a reverse-biased semiconductor diode. Previous descriptions of emission in silicon diodes did not adapt the density of states to a one-dimensional geometry, and did not provide an absolute power spectral density. This framework suggests that significantly more emitted power may yet be possible from these devices. This is, to the knowledge of the inventors of the present disclosure, the first single-mode waveguide broadband silicon emitter, and the highest reported intensity of any silicon emitter. Notably, since the fabrication has been carried out in a PIC foundry, it can be integrated into the component library for this, and other, state-of-the-art foundries.

As the applications for silicon photonics expand beyond data communications and telecommunications, broadband on-chip light sources may become increasing valuable. These sources can be used for in-situ broadband component characterization (see, Reference [43]), for wafer-scale process control (see, References [34] and [35]), for infrared absorption spectroscopy (see, References [21] and [24], and/or for Fourier-transform infrared spectroscopy (see, Reference [44]). When combined with on-chip spectrometers, spectral filters, or even placed inside of high-Q waveguide cavities (see, Reference [45]), this source may fill a critical gap as the engine of partially-integrated or fully-integrated spectroscopy systems on a chip. Devices disclosed herein have been fabricated at AIM Photonics using a process that is similar to and/or compatible with that of the standard Base Active Multi-Project Wafer. The silicon layer is 220 nm thick and can be fabricated either as ridge (full etch, 480 nm wide) or rib (half-etch, 550 nm wide) single-mode waveguides. The waveguides are clad in SiO₂. According to some embodiments discussed above with respect to FIGS. 1A-D, 2A-D, 3A-D, and/or 4A-D, a ridge waveguide 109t outside of the emission region may adiabatically convert to a rib waveguide 109c in the 60 μm long emission region. As shown in FIGS. 1A-D, 2A-D, 3A-D, and/or 4A-D, the undoped rib waveguide 109 is placed laterally between p-type silicon layer 115p (also referred to as a p-doped Si slab) and n-type silicon layer 119n (also referred to as an n-doped Si slab). Both p-type silicon layer 115p and n-type silicon layer 119n are ohmically contacted by respective metal layers 125 and 129 that may be used to provide charge injection and/or biasing. The width of the undoped gap between the n-doped and p-doped regions (d_{in,e}) may be 400 nm or 800 nm in the example devices presented herein.

According to some embodiments of inventive concepts, broadband silicon-based light sources may be directly integrated in photonic integrated circuits (PICs) fabricated in a standard optical foundry. Such light sources may thus provide on-chip laser and/or light sources for PICs to provide optical systems on chip for applications ranging from chemical sensing to electronic warfare to quantum science. As disclosed herein, such PIC light sources have been fabricated using standard foundry processes, materials, and dimensions (i.e., processes, materials, and dimensions used by AIM Photonics) to: demonstrate broadband light emission in a silicon waveguide; demonstrate PIC characterization using this silicon waveguide light source; and demonstrate chemical sensing (absorption spectroscopy) using this silicon waveguide light source and a silicon nitride sensing chip. Such silicon-based light sources may also be waveguide integrated allowing seamless coupling between the light source and waveguide.

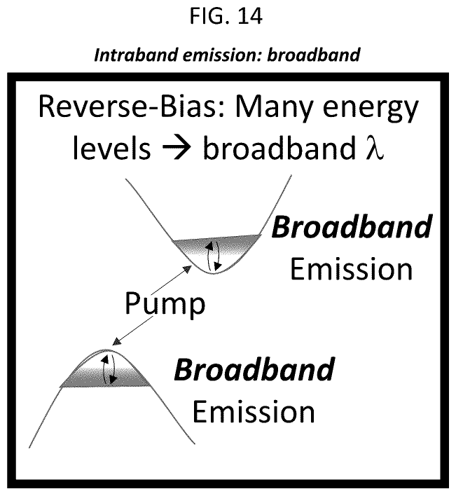

Moreover, silicon-based light sources according to some embodiments of inventive concepts may use reverse bias operation to provide broadband intraband emission as shown in FIG. 14. Using reverse bias operation, many energy levels yield broadband output emission from visible to near-infrared wavelengths.

According to some embodiments of inventive concepts, a width W_{wg,e} of the rib waveguide in the emission region may be greater than a width W_{wg,t} of the ridge waveguide in the transmission region. In such embodiments, a width of the waveguide may narrow linearly from width W_{wg,e} to width W_{wg,t} to provide coupling between the P-i-N diode rib waveguide and the ridge transmission waveguide. In embodiments of FIGS. 2A-D, 3A-D, and/or 4A-D, such linear narrowing may begin where waveguide 109 extends beyond intrinsic silicon layers 115i and 119i. For example, the waveguide may linearly narrow from a rib waveguide width of 550 nm to a ridge waveguide width of 480 nm. Moreover, such structures may provide an increased/maximum overlap of electric field modes coupling to the waveguide.

According to some embodiments of inventive concepts, P-i-N waveguide diodes may provide: PIC component metrology for on-chip measurement of photonic components; and/or chip-scale chemical sensor systems that can be realized by incorporating the waveguide diode as a broadband optical source with a waveguide-based sensor on a single chip. Moreover, such P-i-N waveguide diodes may be incorporated in a foundry process development kit (PDK) component library for use on-chip with other devices/structures currently available in the PDK or that may become available in the PDK in the future.

According to some embodiments of inventive concepts illustrated in FIGS. 2A-D, a photonic integrated circuit includes substrate 101 (e.g., a semiconductor silicon substrate), semiconductor waveguide 109 (e.g., a semiconductor silicon waveguide) on a surface of substrate 101, p-type semiconductor layer 115p on the surface of substrate 101 on a first side of semiconductor waveguide 109, and n-type semiconductor layer 119n on the surface of substrate 101 on a second side of semiconductor waveguide. Region 109e of semiconductor waveguide 109 is thus between p-type and n-type semiconductor layers 119p and 119n. Moreover, first portion 109p of semiconductor waveguide 109 adjacent to p-type semiconductor layer 115p is p-type, second portion 109n of semiconductor waveguide 109 adjacent to n-type semiconductor layer 119n is n-type, and third portion 109i of semiconductor waveguide 109 (between first and second portions 109n and 109p) is intrinsic. Accordingly, p-type semiconductor layer 119p, first portion 109p of semiconductor waveguide 109, n-type semiconductor layer 119n, second portion 109n of semiconductor waveguide 109, and third portion 109i of semiconductor waveguide 109 define a radiation emitting P-i-N diode configured to emit radiation through semiconductor waveguide 109.

As further shown in embodiments of FIGS. 2A-D, thickness T_{wg} of semiconductor waveguide 109 is greater than thickness Tp,n of at least a portion of p-type semiconductor layer 115p, and thickness T_{wg} of semiconductor waveguide 109 is greater than thickness Tp,n of at least a portion of n-type semiconductor layer 119n. Accordingly, semiconductor waveguide 109, p-type semiconductor layer 115p, and n-type semiconductor layer 119n together define a rib waveguide.

As further shown in embodiments of FIGS. 2A-D, first cladding layer 105 is between semiconductor waveguide 109 (including p-type, n-type, and intrinsic portions 109p, 109n, and 109i) and substrate 101, between p-type semiconductor layer 115p and substrate 101, and between n-type semiconductor layer 119n and substrate 101, and second cladding layer 121 is on first cladding layer 105 so that semiconductor waveguide 109 is between first and second cladding layers 105 and 121, p-type semiconductor layer 115p is between first and second cladding layers 105 and 121, and n-type semiconductor layer 119n is between first and second cladding layers 105 and 121. Moreover, first and second cladding layers 105 and 121 may be respective first and second dielectric cladding layers (e.g., first and second silicon dioxide cladding layers).

According to some embodiments of inventive concepts illustrated in FIGS. 3A-D, a photonic integrated circuit includes substrate 101, semiconductor waveguide 109 (e.g., a semiconductor silicon waveguide) on a surface of substrate 101, p-type semiconductor layer 115p on the surface of substrate 101, and n-type semiconductor layer 119n on the surface of substrate 101. Moreover, p-type and n-type semiconductor layers 115p and 119n are on respective first and second sides of semiconductor waveguide 109. Region 109e of semiconductor waveguide 109 is between p-type and n-type semiconductor layers 119p and 119n, and region 109e of semiconductor waveguide 109 between p-type and n-type semiconductor layers includes an intrinsic portion 109i. Accordingly, p-type semiconductor layer 119p, n-type semiconductor layer 119n, and region 109e of semiconductor waveguide 109 between n-type and p-type semiconductor layers 119n and 119p define a radiation emitting P-i-N diode configured to emit radiation through semiconductor waveguide 109.

As further shown in embodiments of FIGS. 3A-D, thickness T_{wg} of semiconductor waveguide 109 is greater than thickness Tp,n of at least a portion of p-type semiconductor layer 115p, and thickness T_{wg} of semiconductor waveguide 109 is greater than thickness Tp,n of at least a portion of n-type semiconductor layer 119n. Accordingly, semiconductor waveguide 109, p-type semiconductor layer 115p, and n-type semiconductor layer 119n together define a rib waveguide.

As further shown in embodiments of FIGS. 3A-D, first cladding layer 105 is between semiconductor waveguide 109 and substrate 101, between p-type semiconductor layer 115p and substrate 101, and between n-type semiconductor layer 119n and substrate 101. Second cladding layer 121 is on first cladding layer 105 so that semiconductor waveguide 109 is between first and second cladding layers 105 and 121, p-type semiconductor layer 115p is between first and second cladding layers 105 and 121, and n-type semiconductor layer 119n is between first and second cladding layers 105 and 121. Moreover, first and second cladding layers 105 and 121 may be respective first and second dielectric cladding layers (e.g., first and second silicon dioxide cladding layers).

According to some embodiments of inventive concepts illustrated in FIGS. 4A-D, a photonic integrated circuit includes substrate 101, semiconductor waveguide 109 (e.g., a semiconductor silicon waveguide) on a surface of substrate 101, p-type semiconductor layer 115p on the surface of substrate 101, first intrinsic semiconductor layer 115i on substrate 101 between p-type semiconductor layer 115p and semiconductor waveguide 109, n-type semiconductor layer 119n on the surface of substrate 101, and second intrinsic semiconductor layer 119i on substrate 101 between n-type semiconductor layer 119n and semiconductor waveguide 109. Moreover, p-type semiconductor layer 115p and first intrinsic semiconductor layer 115i are on a first side of semiconductor waveguide 109, and n-type semiconductor layer 115n and second intrinsic semiconductor layer 119i are on a second side of semiconductor waveguide 109. In addition, region 109e of semiconductor waveguide includes an intrinsic portion 109i. Accordingly, region 109e of semiconductor waveguide 109 is between p-type and n-type semiconductor layers 119p and 119n. P-type semiconductor layer 119p, first intrinsic semiconductor layer 115i, n-type semiconductor layer 119n, second intrinsic semiconductor layer 119i, and region 109e of semiconductor waveguide 109 between n-type and p-type semiconductor layers 119n and 119p thus define a radiation emitting P-i-N diode configured to emit radiation through semiconductor waveguide 109.

As further shown in embodiments of FIGS. 4A-D, thickness T_{wg} of semiconductor waveguide 109 is greater than thickness T_{p,n} of at least a portion of p-type semiconductor layer 115p and first intrinsic semiconductor layer 115i. Similarly, thickness T_{wg} of semiconductor waveguide 109 is greater than thickness T_{p,n} of at least a portion of n-type semiconductor layer 119n and second intrinsic semiconductor layer 119i. Accordingly, semiconductor waveguide 109 together with at least one of first intrinsic semiconductor layer 115i, p-type semiconductor layer 115p, second intrinsic semiconductor layer 119i, and/or n-type semiconductor layer 119n define a rib waveguide.

As further shown in embodiments of FIGS. 4A-D, first cladding layer 105 is between semiconductor waveguide 109 and substrate 101, between p-type semiconductor layer 115p and substrate 101, between first intrinsic semiconductor layer 115i and substrate 101, between n-type semiconductor layer 119n and substrate 101, and between second intrinsic semiconductor layer 119i and substrate 101. In addition, second cladding layer 121 is on first cladding layer 105 so that semiconductor waveguide 109 is between first and second cladding layers 105 and 121, p-type semiconductor layer 115p is between first and second cladding layers 105 and 121, first intrinsic semiconductor layer 115i is between first and second cladding layers 105 and 121, n-type semiconductor layer 119n is between first and second cladding layers 105 and 121, and second intrinsic semiconductor layer 119i is between first and second cladding layers 105 and 121. Moreover, first and second cladding layers 105 and 121 may be respective first and second dielectric cladding layers (e.g., first and second silicon dioxide cladding layers).

According to any of the embodiments of FIGS. 2A-D, FIGS. 3A-D, and/or FIGS. 4A-D, semiconductor waveguide 109 may extend between p-type and n-type semiconductor layers 115p and 119n and away from the p-type and n-type semiconductor layers on the surface of substrate 101, and the radiation emitting P-i-N diode may be configured to emit the radiation through semiconductor waveguide 109 away from the radiation emitting P-i-N diode in a direction 141 parallel with respect to the surface of substrate 101.

According to any of the embodiments of FIGS. 2A-D, FIGS. 3A-D, and/or FIGS. 4A-D, driving circuit 501 may be electrically coupled with p-type semiconductor layer 115p and n-type semiconductor layer 119n as discussed above with respect to FIG. 5, and the radiation emitting P-i-N diode may be configured to emit the radiation responsive to an electrical signal applied by driving circuit 501 across p-type and n-type semiconductor layers 115p and 119n. Both P-i-N diode and driving circuit 501 may thus be integrated on a common substrate to provide a photonic integrated circuit (PIC) device. More particularly, driving circuit 501 may be configured to apply the electrical signal by controlling an electrical current through p-type and n-type semiconductor layers 115p and 119n. Driving circuit 501 may be configured to apply a reverse biased electrical signal across p-type and the n-type semiconductor layers 115p and 119n, and the radiation emitting P-i-N diode may be configured to emit the radiation responsive to the reverse biased electrical signal. In an alternative, driving circuit 501 may be configured to apply a forward biased electrical signal across p-type and n-type semiconductor layers 115p and 119n, and the radiation emitting P-i-N diode may be configured to emit the radiation responsive to the forward biased electrical signal. For example, the radiation emitting P-i-N diode may be configured to emit broadband radiation from visible to infrared wavelengths, or the radiation emitting P-i-N diode may be configured to emit narrowband radiation near the silicon bandedge at 1100 nm wavelength.

According to any of the embodiments of FIGS. 2A-D, FIGS. 3A-D, and/or FIGS. 4A-D, substrate 101 may be a semiconductor substrate, such as a semiconductor silicon substrate. In addition, the photonic integrated circuit device may include at least one of: an NMOS transistor having n-type source and drain regions in the surface of the semiconductor substrate; and/or a PMOS transistor having p-type source and drain regions in the surface of the semiconductor substrate. Moreover, semiconductor waveguide 109 may be a semiconductor silicon waveguide, p-type semiconductor layer 115p may be p-type silicon, and n-type semiconductor layer 119n may be n-type silicon.

According to any of the embodiments of FIGS. 2A-D, FIGS. 3A-D, and/or FIGS. 4A-D, any number of other electronic and/or optical devices 505 may be integrated with the P-i-N diode on substrate 101 and optically coupled to receive radiation emitted by the P-i-N diode via waveguide 109. By way of example, any one or more of the following electronic and/or optical devices 505 may be integrated with the P-i-N diode on substrate 101: a photodiode, a spectrometer, a spectral filter, a spiral waveguide, etc. A photodiode on the substrate 101 may be configured to receive at least a portion of the radiation emitted from the radiation emitting P-i-N diode through semiconductor waveguide 109. A spectrometer on substrate 101 may be configured to receive at least a portion of the radiation emitted from the radiation emitting P-i-N diode through semiconductor waveguide 109. A spectral filter (e.g., a Mach-Zehnder interferometer, a lattice filter, a Fabry-Perot cavity, a microring resonator cavity, a photonic crystal cavity, a directional coupler, an integrated photonic component with a wavelength-dependent response, etc.) on substrate 101 may be configured to filter at least a portion of the radiation emitted from the radiation emitting P-i-N diode through semiconductor waveguide 109. A spiral waveguide on the substrate 101 may be configured to receive at least a portion of the radiation emitted from the radiation emitting P-i-N diode through semiconductor waveguide 109. With a spiral waveguide, dielectric cladding layer 121 may be provided on semiconductor waveguide 109 such that semiconductor waveguide 109 is between dielectric cladding layer 121 and substrate 101. A sensing portion of the spiral waveguide may be free of dielectric cladding layer 121, and the sensing portion of the spiral waveguide may be configured to receive a chemical analyte. Moreover, a sensor may be coupled with the spiral waveguide, with the sensor being configured to determine a property of the chemical analyte based on a change in an absorption spectrum of the radiation received by the spiral waveguide from the radiation emitting P-i-N diode.

Example Embodiments of inventive concepts of the present disclosure are provided below.

Embodiment 1. A photonic integrated circuit device comprising: a substrate; a semiconductor waveguide on a surface of the substrate; a p-type semiconductor layer on the surface of the substrate, wherein the p-type semiconductor layer is on a first side of the semiconductor waveguide; and an n-type semiconductor layer on the surface of the substrate, wherein the n-type semiconductor layer is on a second side of the semiconductor waveguide so that a region of the semiconductor waveguide is between the p-type and n-type semiconductor layers and so that the p-type semiconductor layer, the n-type semiconductor layer, and the region of the semiconductor waveguide between the n-type and p-type semiconductor layers define a radiation emitting diode configured to emit radiation through the semiconductor waveguide.

Embodiment 2. The photonic integrated circuit device according to Embodiment 1, wherein the semiconductor waveguide extends between the p-type and n-type semiconductor layers and away from the p-type and n-type semiconductor layers on the surface of the substrate, and wherein the radiation emitting diode is configured to emit the radiation through the semiconductor waveguide away from the radiation emitting diode in a direction parallel with respect to the surface of the substrate.

Embodiment 3. The photonic integrated circuit device according to any of Embodiments 1-2, wherein the region of the semiconductor waveguide between the p-type and n-type semiconductor layers includes an intrinsic portion so that the radiation emitting diode comprises a radiation emitting P-i-N diode.

Embodiment 4. The photonic integrated circuit device according to Embodiment 3, wherein a width of the intrinsic portion is at least 400 nm between the p-type and n-type semiconductor layers.

Embodiment 5. The photonic integrated circuit device according to any of Embodiments 1-4, wherein a thickness of the semiconductor waveguide is greater than a thickness of at least a portion of the p-type semiconductor layer, and wherein the thickness of the semiconductor waveguide is greater than a thickness of at least a portion of the n-type semiconductor layer.

Embodiment 6. The photonic integrated circuit device according to Embodiment 5, wherein the thickness of the semiconductor waveguide is at least 25% greater than the thickness of the portion of the p-type semiconductor layer and the thickness of the n-type semiconductor layer; and/or wherein the thickness of the semiconductor waveguide is at least 50% greater than the thickness of the portion of the p-type semiconductor layer and the thickness of the n-type semiconductor layer; and/or wherein the thickness of the semiconductor waveguide is at least 100% greater than the thickness of the portion of the p-type semiconductor layer and the thickness of the n-type semiconductor layer.

Embodiment 7. The photonic integrated circuit device according to any of Embodiments 5-6, further comprising: a first intrinsic semiconductor layer on the substrate between the p-type semiconductor layer and the semiconductor waveguide, wherein the thickness of the semiconductor waveguide is at least 25% greater than a thickness of the first intrinsic semiconductor layer, and/or wherein the thickness of the semiconductor waveguide is at least 50% greater than a thickness of the first intrinsic semiconductor layer, and/or wherein the thickness of the semiconductor waveguide is at least 100% greater than a thickness of the first intrinsic semiconductor layer; and a second intrinsic semiconductor layer on the substrate between the n-type semiconductor layer and the semiconductor waveguide, wherein the thickness of the semiconductor waveguide is at least 25% greater than a thickness of the second intrinsic semiconductor layer, and/or wherein the thickness of the semiconductor waveguide is at least 50% greater than a thickness of the second intrinsic semiconductor layer, and/or wherein the thickness of the semiconductor waveguide is at least 100% greater than a thickness of the second intrinsic semiconductor layer.

Embodiment 8. The photonic integrated circuit device according to any of Embodiments 5-6, wherein a first portion of the semiconductor waveguide adjacent to the p-type semiconductor layer is p-type, and wherein a second portion of the semiconductor waveguide adjacent to the n-type semiconductor layer is n-type.

Embodiment 9. The photonic integrated circuit device according to any of Embodiments 1-8, further comprising: a driving circuit electrically coupled with the p-type semiconductor layer and the n-type semiconductor layer, wherein the radiation emitting diode is configured to emit the radiation responsive to an electrical signal applied across the p-type and the n-type semiconductor layers.

Embodiment 10. The photonic integrated circuit device according to Embodiment 9, wherein the driving circuit is configured to apply a reverse biased electrical signal across the p-type and the n-type semiconductor layers, and wherein the radiation emitting diode is configured to emit the radiation responsive to the reverse biased electrical signal.

Embodiment 11. The photonic integrated circuit device according to any of Embodiments 1-10, wherein the radiation emitting diode is configured to emit the radiation at wavelengths greater than about 900 nm.

Embodiment 12. The photonic integrated circuit device according to any of Embodiments 1-11, wherein the radiation emitting diode is configured to emit the radiation over a wavelength band of at least 400 nm, and/or over a wavelength band of at least 700 nm.

Embodiment 13. The photonic integrated circuit device according to any of Embodiments 1-12, wherein the radiation emitting diode is configured to couple at least 1 nW of radiation power through the semiconductor waveguide in the direction parallel with respect to the surface of the substrate, and/or wherein the radiation emitting diode is configured to couple at least 5 nW of radiation power through the semiconductor waveguide in the direction parallel with respect to the surface of the substrate.

Embodiment 14. The photonic integrated circuit device according to any of Embodiments 1-13, further comprising: a first cladding layer on the substrate, wherein the first cladding layer is between the semiconductor waveguide and the substrate, wherein the first cladding layer is between the p-type semiconductor layer and the substrate, and wherein the first cladding layer is between the n-type semiconductor layer and the substrate; and a second cladding layer on the first dielectric layer, wherein the semiconductor waveguide is between the first and second cladding layers, wherein the p-type semiconductor layer is between the first and second cladding layers, and wherein the n-type semiconductor layer is between the first and second cladding layers.

Embodiment 15. The photonic integrated circuit device according to Embodiment 14, wherein the first and second cladding layers comprise respective first and second dielectric layers, and/or wherein the first and second cladding layers comprise respective first and second silicon dioxide layers.

Embodiment 16. The photonic integrated circuit device according to any of Embodiments 1-15, wherein the substrate comprises a semiconductor substrate.

Embodiment 17. The photonic integrated circuit device according to Embodiment 16, further comprising at least one of: an NMOS transistor having n-type source and drain regions in the surface of the semiconductor substrate; and/or a PMOS transistor having p-type source and drain regions in the surface of the semiconductor substrate.

Embodiment 18. The photonic integrated circuit device according to any of Embodiments 1-17, wherein the semiconductor waveguide comprises a semiconductor silicon waveguide, and/or wherein the p-type semiconductor layer comprises p-type silicon, and/or wherein the n-type semiconductor layer comprises n-type silicon.

Embodiment 19. The photonic integrated circuit device according to any of Embodiments 1-18, further comprising: a photodiode on the substrate, wherein the photodiode is configured to receive at least a portion of the radiation emitted from the radiation emitting diode through the semiconductor waveguide.

Embodiment 20. The photonic integrated circuit device according to any of Embodiments 1-19, further comprising: a spectrometer on the substrate, wherein the spectrometer is configured to receive at least a portion of the radiation emitted from the radiation emitting diode through the semiconductor waveguide.

Embodiment 21. The photonic integrated circuit device according to any of Embodiments 1-20, further comprising: a spectral filter on the substrate, wherein the spectral filter is configured to filter at least a portion of the radiation emitted from the radiation emitting diode through the semiconductor waveguide.

Embodiment 22. The photonic integrated circuit device according to any of Embodiments 1-21, further comprising: a spiral waveguide on the substrate, wherein the spiral waveguide is configured to receive at least a portion of the radiation emitted from the radiation emitting diode through the semiconductor waveguide.

A listing of cited the References is provided below. References are cited in the disclosure above with a number corresponding to the number associated with each reference below. The disclosures of each of these references are hereby incorporated herein in their entireties by reference.
Reference [1]. Green, M. A., et al., “Efficient silicon light-emitting diodes,” Nature (UK), Vol. 412, pages 805-808, 23 Aug. 2001.
Reference [2]. Komljenovic, T., et al., “Photonic integrated circuits using heterogeneous integration on silicon,” Proceedings of the IEEE (US), Vol. 106, No. 12, pages 2246-2257, 2018.
Reference [3]. Shang, C., et al., “High temperature reliable quantum-dot lasers on Si with misfit and threading dislocation filters,” Optica (US), Vol. 8, Issue 5, pages 749-754, May 2021.
Reference [4]. Han, Y., et al., “Recent advances in light sources on silicon,” Adv. Opt. Photon. (US), Vol. 14, No. 3, pages 404-454, September 2022.
Reference [5]. Chynoweth, A. G., et al., “Photon emission from avalanche breakdown in silicon,” Phys. Rev. (US), Vol. 102, pages 369-376, 15 Apr. 1956.
Reference [6]. Michaelis, W., et al., “Radiative recombination in silicon p-n junctions” Phys. Stat. Sol. (DE), Vol. 36, No. 1, pages 311-319, 1969.
Reference [7]. Ong, T.-C., et al., “Photon generation in forward biased silicon p-n junctions,” IEEE Electron Device Letters (US), Vol. EDL 4, No. 12, pages 460-462, December 1983.
Reference [8]. Zhao, J., et al., “High-efficiency optical emission, detection, and coupling using silicon diodes,” J. Appl. Phys. (US), Vol. 92, Issue 6, pages 2977-2979 Sep. 15, 2002.
Reference [9]. Newman, R., “Visible light from a silicon p-n junction,” Phys. Rev. (US), Vol. 100, No. 2, pages 700-703, Oct. 15, 1955.
Reference [10]. Obeidat, A. T., et al., “A model for visible photon emission from reverse-biased silicon p-n junctions,” Appl. Phys. Lett. (US), Vol. 70, No. 4, pages 470-471, Jan. 27, 1997.
Reference [11]. Xu, K., et al., “Light emission in silicon: from device physics to applications,” Proc. of SPIE (US), Vol. 9667, pages 966702-1 to 966702-10, Nov. 6, 2015.
Reference [12]. Hirschman, K. D., et al., “Silicon-based visible light-emitting devices integrated into microelectronic circuits.” Nature (UK), Vol. 384, pages 338-341, Nov. 28, 1996.
Reference [13]. Ng, W. L., et al., “An efficient room-temperature silicon-based light-emitting diode,” Nature (UK), Vol. 410, pages 192-194, Mar. 8, 2001.
Reference [14]. Li, Z., et al., “A sub-wavelength Si LED integrated in a CMOS platform,” Nat. Commun. (UK), Vol. 14, Article No. 882, 9 pages, Feb. 16, 2023.
Reference [15]. Robinson, J. T., et al., “On-chip gas detection in silicon optical microcavities,” Opt. Express (US), Vol. 16, Issue 6, pages 4296-4301 Mar. 13, 2008.
Reference [16]. Cognetti, J. S., et al., “Disposable photonics for cost-effective clinical bioassays: application to covid-19 antibody testing,” Lab Chip (UK), Vol. 21, Issue 15, pages 2913-2921, 2021.
Reference [17]. Dhakal, A., et al., “Evanescent excitation and collection of spontaneous Raman spectra using silicon nitride nanophotonic waveguides,” Opt. Lett. (US), Vol. 39, Issue 13, pages 4025-4028 Jul. 1, 2014.
Reference [18]. Holmstrom, S. A., et al., “Trace gas Raman spectroscopy using functionalized waveguides,” Optica (US), Vol. 3, Issue 8, pages 891-896, Aug. 8, 2016.
Reference [19]. Zheng, S. N., et al., “Microring resonator-assisted fourier transform spectrometer with enhanced resolution and large bandwidth in single chip solution,” Nat. Commun. (UK), Vol. 10, Issue 1, 2349 May 28, 2019.
Reference [20]. Ryckeboer, E., et al., “Glucose sensing by waveguide-based absorption spectroscopy on a silicon chip,” Biomed. Opt. Express (US), Vol. 5, Issue 5, pages 1636-1648 Apr. 24, 2014.
Reference [21]. Tyndall, N. F., et al., “Figure-of-merit characterization of hydrogen-bond acidic sorbents for waveguide-enhanced Raman spectroscopy,” ACS Sens. (US), Vol. 5, Issue 3, pages 831-836, Mar. 10, 2020.
Reference [22]. Nitkowski, A., et al., “Cavity-enhanced on-chip absorption spectroscopy using microring resonators,” Opt. Express (US), Vol. 16, Issue 16, pages 11930-11936, Aug. 4, 2008.
Reference [23]. Stievater, T. H., et al., “Trace gas absorption spectroscopy using functionalized microring resonators,” Opt. Lett. (US), Vol. 39, Issue 4, pages 969-972, Feb. 15, 2014.
Reference [24]. Tombez, L., “Methane absorption spectroscopy on a silicon photonic chip,” Optica (US), Vol. 4, No. 11, pages 1322-1325 Oct. 26, 2017.
Reference [25]. El Ghazi, H., “Analysis of silicon light emission under breakdown condition using an indirect intraband model,” Optics Commun. (US), Vol. 281, Issue 12, pages 3320-3323 Jun. 15, 2008.
Reference [26]. Lacaita, A. L., et al. “On the bremsstrahlung origin of hot-carrier-induced photons in silicon devices,” IEEE Transactions on Electron Devices (US), Vol. 40, Issue 3, pages 577-582, March 1993.
Reference [27]. Akil, N., et al., “Photon generation by silicon diodes in avalanche breakdown,” Appl. Phys. Lett. (US), Vol. 73, No. 7, pages 871-872, Aug. 17, 1998.
Reference [28]. Wurfel, P., “The chemical potential of radiation,” J. Phys. C: Solid State Phys. (UK), Vol 15, No. 18, pages 3967-3985, 1982.
Reference [29]. Fohrmann, L. S., et al., “Single mode thermal emission,” Opt. Express (US), Vol. 23, Issue 21, pages 27672-27682, Oct. 13, 2015.
Reference [30]. Schroder, D. K., et al., “Free carrier absorption in silicon,” IEEE Journal of Solid-State Circuits (US), Vol. 13, Issue 1, pages 180-187, February 1978.
Reference [31]. Jacoboni, C., et al., “A review of some charge transport properties of silicon,” Solid-State Electronics (UK), Vol. 20, Issue 2, pages 77-89, February 1977.
Reference [32]. Schmitt, S. W., et al. “All-silicon polarized light source based on electrically excited whispering gallery modes in inversely tapered photonic resonators,” APL Mater. (US), Vol. 8, Issue 6, pages 061110 Jan. 8, Jun. 18, 2020.
Reference [33]. Tyndall, N. F., et al., “Ultrabroadband lattice filters for integrated photonic spectroscopy and sensing, Optical Engineering (US), Vol. 57, No. 12, pages 127103 Jan. 5, December 2018.
Reference [34]. Xing, Y., et al., “Compact silicon photonics circuit to extract multiple parameters for process control monitoring,” OSA Continuum (US), Vol. 3, Issue 2, pages 379-390, Feb. 15, 2020.
Reference [35]. Stievater, T. H., et al., “Optical and geometric parameter extraction for photonic integrated circuits,” Opt. Express (US), Vol. 30, Issue 9, pages 14453-14460, Apr. 25, 2022.
Reference [36]. Tyndall, N. F., et al., “Passive photonic integration of lattice filters for wave guide enhanced Raman spectroscopy,” Opt. Express (US), Vol. 28, Issue 23, pages 34927-34934, Nov. 9, 2020.
Reference [37]. Curcio, J. A., et al., “The near infrared absorption spectrum of liquid water,” J. Opt. Soc. Am. (US), Vol. 41, Issue 5, pages 302-304, May 1, 1951.
Reference [38]. Sani, E., et al., “Spectral optical constants of ethanol and isopropanol from ultraviolet to far infrared,” Opt. Mater. (NL), Vol. 60, pages 137-141, October 2016.
Reference [39]. Souza, M. C. M. M., et al., Fourier transform spectrometer on silicon with thermo-optic non-linearity and dispersion correction,” Nature Communications (UK), Vol. 9, Article No. 665, Feb. 4, 2018.
Reference [40]. Yang, Z., et al., “Miniaturization of optical spectrometers,” Science (US), Vol. 371, Issue 6528, 0722 Jan. 29, 2021.
Reference [41]. Bryan, M. R., et al., “Biosensing with silicon nitride microring resonators integrated with an on chip filter bank spectrometer,” ACS Sens. (US), Vol. 8, Issue 2, pages 739-747, Feb. 14, 2023.
Reference [42]. Tyndall, N. F., et al., “Backscatter WERS for trace chemical analyte detection using a handheld spectrometer,” Proc. of SPIE (US), Volume 11416, pages 1141603-1 to 1141603-6, Apr. 24, 2020.
Reference [43]. Tyndall, N. F., et al., “Mode-crossing spectroscopy for photonic waveguide characterization,” APL Photon. (US), Vol. 4, Issue 10, 106107, pages 106107-1 to 106107-6, Oct. 11, 2019.
Reference [44]. Kita, D. M., et al. “High-performance and scalable on-chip digital fourier transform spectroscopy,” Nat. Commun. (UK), Vol. 9, No. 1, Article No. 4405 Oct. 23, 2018.
Reference [45]. de Cea, M., et al., “Native waveguide light emitting diodes in silicon electronic-photonic platforms,” in Conference on Lasers and Electro-Optics, Technical Digest Series, 2 pages, paper SM3N.3, Optica Publishing Group (US), 2022.
Reference [46]. Camacho-Aguilera, R. E., et al., “An electrically pumped germanium laser,” Opt. Express (US), Vol. 20, Issue 10, pages 11316-11320, May 2, 2012.
Reference [47]. Rong, H., et al., “A continuous-wave Raman silicon laser,” Nature (UK), Vol. 433, pages 725-728, 2005.
Reference [48]. de Cea, M., et al., “Single-mode waveguide-coupled light emitting diodes in unmodified silicon photonics fabrication processes,” APL Photon. (US), Vol. 8, Issue 8, pages 081301-1 to 081301-8, Aug. 1, 2023.
Reference [49]. Van Acoloyen, K., et al., “Off-chip beam steering with a one-dimensional optical phased array on silicon-on-insulator,” Opt. Lett. (US), Vol. 34, No. 9, pages 1477-1479 May 1, 2009.
Reference [50]. O'Regan, B. J., et al., “Silicon photonic crystal thermal emitter at near-infrared wavelengths,” Sci. Rep. (UK), Vol. 5, Article No. 13415, 8 pages, Aug. 21, 2015.
Reference [51]. Singh, N., et al., “Octave-spanning coherent supercontinuum generation in silicon on insulator from 1.06 μm to beyond 2.4 μm,” Light: Science & Applications (UK), Vol. 7, 8 pages, 2018.
Reference [52]. Zia, H., et al., “Ultraefficient on-Chip Supercontinuum Generation from Sign-Alternating-Dispersion Waveguides,” Advanced Photonics Research (US), Vol. 4, Issue 5, 9 pages, May 2023.
Reference [53]. Dwivedi, S., et al., “Experimental Extraction of Effective Refractive Index and Thermo-Optic Coefficients of Silicon-on-Insulator Waveguides Using Interferometers,” J. of Lightwave Tech. (US), Vol. 33, Issue 21, pages 4471-4477 Nov. 1, 2015.
Reference [54]. van Niekerk, M., et al., “Wafer-Scale-Compatible Substrate Undercut for Ultra-Efficient SOI Thermal Phase Shifters,” Conference on Lasers and Electro-Optics (US), 2 pages, 2022.
Reference [55]. El Ghazi, H., et al., “Analysis of temperature and 1 MeV proton irradiation effects on the light emission in bulk silicon (npn) emitter-base bipolar junctions,” Optics Communications (NL), Vol. 280, Issue 2, pages 278-284, December 2007.
Reference [56]. Webster, M. A., et al., “Width Dependence of Inherent TM-Mode Lateral Leakage Loss in Silicon-On-Insulator Ridge Waveguides,” IEEE Photonics Tech. Lett. (US), Vol. 19, Issue 6, pages 429-431, Mar. 15, 2007.
Reference [57]. Boyd, R. W., et al., “Photon bunching and the photon-noise-limited performance of infrared detectors,” Infrared Physics (NL), Vol. 22, Issue 3, pages 157-162, May 1982.
Reference [58]. Green, M.A., “Self-consistent optical properties of intrinsic silicon at 300 K including temperature coefficients,” Solar Energy Materials & Solar Cells (NL), Vol. 92, Issue 11, pages 1305-1310 Nov. 2008.
Reference [59]. Kano, K., “Semiconductor Devices,” Prentice Hall, Upper Saddle River, New Jersey (US), 1998.

Additional Disclosure is provided below.

In the drawings presented herein, sizes and/or shapes of elements may be exaggerated for clarity and conveniences of explanation.

The terminology used herein is for the purpose of describing particular embodiments only and is not intended to be limiting of inventive concepts. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. The term “and/or” includes any and all combinations of one or more of the associated listed items.

Spatially relative terms, such as “over,” “under,” “top,” “bottom,” “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, third, etc. may be used herein to describe various elements, these elements should not be limited by these terms. These terms are only used to distinguish one element from another element. Thus, a first element discussed herein could be termed a second element without departing from the scope of the present inventive concepts.

It will also be understood that when an element is referred to as being “on,” “connected” to/with, or “coupled” to/with another element, it can be directly on, directly connected to/with, or directly coupled to/with the other element, or intervening elements may be present. In contrast, when an element is referred to as being “directly on”, “directly connected” to/with, or “directly coupled” to/with another element, there are no intervening elements present. Moreover, if an element is referred to as being “on” another element, no spatial orientation is implied such that the element can be over the other element, under the other element, on a side of the other element, etc.

Embodiments are described herein with reference to cross-sectional and/or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted/doped region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the present inventive concepts.

Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the description herein.

Unless otherwise defined, all terms (including technical and scientific terms) used herein have the same meaning as commonly understood by one of ordinary skill in the art to which the inventive concepts herein belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While inventive concepts have been particularly shown and described with reference to examples of embodiments thereof, it will be understood that various changes in form and details may be made therein without departing from the spirit of the following claims.

1. A photonic integrated circuit device comprising:
a substrate;
a semiconductor waveguide on a surface of the substrate;
a p-type semiconductor layer on the surface of the substrate, wherein the p-type semiconductor layer is on a first side of the semiconductor waveguide; and
an n-type semiconductor layer on the surface of the substrate, wherein the n-type semiconductor layer is on a second side of the semiconductor waveguide so that a region of the semiconductor waveguide is between the p-type and n-type semiconductor layers and so that the p-type semiconductor layer, the n-type semiconductor layer, and the region of the semiconductor waveguide between the n-type and p-type semiconductor layers define a radiation emitting diode configured to emit radiation through the semiconductor waveguide.

2. The photonic integrated circuit device according to claim 1, wherein the semiconductor waveguide comprises a semiconductor silicon waveguide.

3. The photonic integrated circuit device according to claim 1, wherein the semiconductor waveguide extends between the p-type and n-type semiconductor layers and away from the p-type and n-type semiconductor layers on the surface of the substrate, and wherein the radiation emitting diode is configured to emit the radiation through the semiconductor waveguide away from the radiation emitting diode in a direction parallel with respect to the surface of the substrate.

4. The photonic integrated circuit device according to claim 1, wherein the region of the semiconductor waveguide between the p-type and n-type semiconductor layers includes an intrinsic portion so that the radiation emitting diode comprises a radiation emitting P-i-N diode.

5. The photonic integrated circuit device according to claim 1, wherein a thickness of the semiconductor waveguide is greater than a thickness of at least a portion of the p-type semiconductor layer, and wherein the thickness of the semiconductor waveguide is greater than a thickness of at least a portion of the n-type semiconductor layer.

6. The photonic integrated circuit device according to claim 5, wherein semiconductor waveguide, the p-type semiconductor layer, and the n-type semiconductor layer together define a rib waveguide.

7. The photonic integrated circuit device according to claim 5, further comprising:
a first intrinsic semiconductor layer on the substrate between the p-type semiconductor layer and the semiconductor waveguide wherein a thickness of the semiconductor waveguide is greater than a thickness of the first intrinsic semiconductor layer; and
a second intrinsic semiconductor layer on the substrate between the n-type semiconductor layer and the semiconductor waveguide wherein a thickness of the semiconductor waveguide is greater than a thickness of the second intrinsic semiconductor layer.

8. (canceled)

9. The photonic integrated circuit device according to claim 5, wherein a first portion of the semiconductor waveguide adjacent to the p-type semiconductor layer is p-type, and wherein a second portion of the semiconductor waveguide adjacent to the n-type semiconductor layer is n-type.

10. The photonic integrated circuit device according to claim 1, further comprising:
a driving circuit electrically coupled with the p-type semiconductor layer and the n-type semiconductor layer, wherein the radiation emitting diode is configured to emit the radiation responsive to an electrical signal applied by the driving circuit across the p-type and the n-type semiconductor layers.

11. The photonic integrated circuit device according to claim 10, wherein the driving circuit is configured to apply the electrical signal by controlling an electrical current through the p-type and n-type semiconductor layers.

12. The photonic integrated circuit device according to claim 10, wherein the driving circuit is configured to apply a reverse biased electrical signal across the p-type and the n-type semiconductor layers, and wherein the radiation emitting diode is configured to emit the radiation responsive to the reverse biased electrical signal.

13. The photonic integrated circuit device according to claim 10, wherein the driving circuit is configured to apply a forward biased electrical signal across the p-type and the n-type semiconductor layers, and wherein the radiation emitting diode is configured to emit the radiation responsive to the forward biased electrical signal.

14. The photonic integrated circuit device according to claim 1, wherein the radiation emitting diode is configured to emit broadband radiation from visible to infrared wavelengths, or wherein the radiation emitting diode is configured to emit narrowband radiation near the silicon bandedge at 1100 nm wavelength.

15. The photonic integrated circuit device according to claim 1, further comprising:
a first cladding layer on the substrate, wherein the first cladding layer is between the semiconductor waveguide and the substrate, wherein the first cladding layer is between the p-type semiconductor layer and the substrate, and wherein the first cladding layer is between the n-type semiconductor layer and the substrate; and
a second cladding layer on the first cladding layer, wherein the semiconductor waveguide is between the first and second cladding layers, wherein the p-type semiconductor layer is between the first and second cladding layers, and wherein the n-type semiconductor layer is between the first and second cladding layers.

16. (canceled)

17. (canceled)

18. The photonic integrated circuit device according to claim 1, wherein the substrate comprises a semiconductor substrate.

19. (canceled)

20. The photonic integrated circuit device according to claim 18, further comprising at least one of:
an NMOS transistor having n-type source and drain regions in the surface of the semiconductor substrate; and/or
a PMOS transistor having p-type source and drain regions in the surface of the semiconductor substrate.

21. (canceled)

22. The photonic integrated circuit device according to claim 1, further comprising:
a photodiode on the substrate, wherein the photodiode is configured to receive at least a portion of the radiation emitted from the radiation emitting diode through the semiconductor waveguide.

23. The photonic integrated circuit device according to claim 1, further comprising:
a spectrometer on the substrate, wherein the spectrometer is configured to receive at least a portion of the radiation emitted from the radiation emitting diode through the semiconductor waveguide.

24. The photonic integrated circuit device according to claim 1, further comprising:
a spectral filter on the substrate, wherein the spectral filter is configured to filter at least a portion of the radiation emitted from the radiation emitting diode through the semiconductor waveguide.

25. (canceled)

26. The photonic integrated circuit device according to claim 1, further comprising:
a spiral waveguide on the substrate, wherein the spiral waveguide is configured to receive at least a portion of the radiation emitted from the radiation emitting diode through the semiconductor waveguide.

27. (canceled)
